(19) United States
(12) Patent Application Publication
(10) Pub. No.: US 2024/0188284 A1
(43) Pub. Date: Jun. 6, 2024

(54) SEMICONDUCTOR DEVICES HAVING BIT LINES

(71) Applicant: Samsung Electronics Co., Ltd., Suwon-si (KR)

(72) Inventors: Jongmin Kim, Suwon-si (KR); Chansic Yoon, Suwon-si (KR); Junhyeok Ahn, Suwon-si (KR)

(21) Appl. No.: 18/371,663

(22) Filed: Sep. 22, 2023

(30) Foreign Application Priority Data
Dec. 2, 2022 (KR) 10-2022-0166189

(51) Int. Cl. H10B 12/00

(52) U.S. Cl. CPC H10B 12/482; H10B 12/02; H10B 12/315; H10B 12/485

(57) ABSTRACT

A semiconductor device includes a gate electrode disposed within a cell region of a substrate, each of bit line structure pairs including a first bit line structure and a second bit line structure, and extension portion pairs disposed within an interface region of the substrate, each extension portion pair including a first extension portion and a second extension portion that are connected to the first bit line structure and the second bit line structure, respectively. The bit line structure pairs are spaced apart from each other by a first distance. In each bit line structure pair, the first bit line structure and the second bit line structure are spaced apart from each other by the first distance. In each extension portion pair, the first extension portion and the second extension portion are spaced apart from each other at a second distance less than the first distance.

### CROSS-REFERENCE TO RELATED APPLICATION(S)

This application claims the benefit under 35 USC 119(a) of Korean Patent Application No. 10-2022-0166189 filed on Dec. 2, 2022 in the Korean Intellectual Property Office, the entire disclosure of which is herein incorporated by reference for all purposes.

### BACKGROUND

The present inventive concept relates to a semiconductor device having a bit line.

As demands for high performance, high speed, and/or multifunctionality of semiconductor devices increase, the degree of integration of semiconductor devices is increasing. In manufacturing a semiconductor device with a fine pattern for high integration of semiconductor devices, it is desirable to implement patterns having a fine width or a fine separation distance.

### SUMMARY

Example embodiments provide a semiconductor device having a bit line and an extension portion connected thereto.

According to example embodiments, a semiconductor device includes a substrate including a cell region and an interface region, a gate electrode disposed within the cell region of the substrate and extending in a first horizontal direction that is parallel to an upper surface of the substrate, a plurality of bit line structure pairs crossing the gate electrode and extending in a second horizontal direction that is parallel to the upper surface of the substrate and intersects the first horizontal direction, each bit line structure pair including a first bit line structure and a second bit line structure that are spaced apart from each other in the first horizontal direction, and a plurality of extension portion pairs disposed within the interface region and spaced apart from each other in the first horizontal direction, each extension portion pair including a first extension portion and a second extension portion that are connected to the first bit line structure of a corresponding bit line structure pair and the second bit line structure thereof, respectively. The plurality of bit line structure pairs are spaced apart from each other by a first distance. In each bit line structure pair, the first bit line structure and the second bit line structure are spaced apart from each other by the first distance. In each extension portion pair, the first extension portion and the second extension portion are spaced apart from each other at a second distance less than the first distance. The first distance and the second distance are measured in the first horizontal direction.

According to example embodiments, a semiconductor device includes a substrate including a cell region and an interface region, a gate electrode disposed within the cell region of the substrate and extending in a first horizontal direction that is parallel to an upper surface of the substrate, a plurality of bit line structures crossing the gate electrode and extending in a second horizontal direction intersecting the first horizontal direction, wherein the second horizontal direction is parallel to the upper surface of the substrate, and a plurality of extension portions disposed in the interface region and connected to the plurality of bit line structures, respectively. A connected structure of each of the plurality of extension portions and a corresponding bit line structure of the plurality of bit line structures has a first horizontal width greater than a second horizontal width of the corresponding bit line structure. The first horizontal width and the second horizontal width are measured in the first horizontal direction. A first central axis of each the plurality of extension portions and a second central axis of the corresponding bit line structure extend in the second horizontal direction. The first central axis is aligned with the second central axis. The plurality of bit line structures are spaced apart from each other by a first distance. The plurality of extension portions are spaced apart from each other by a second distance less than the first distance. The first distance and the second distance are measured in the first horizontal direction.

According to example embodiments, a semiconductor device includes a substrate including a cell region and an interface region, a gate electrode disposed within the cell region of the substrate and extending in a first horizontal direction that is parallel to an upper surface of the substrate, a first bit line structure crossing the gate electrode and extending in a second horizontal direction that is parallel to the upper surface of the substrate and intersects the first horizontal direction, a second bit line structure crossing the gate electrode and extending in the second horizontal direction, wherein the second bit line structure is adjacent to the first bit line structure, a first buried contact disposed in a space between the first bit line structure and the second bit line structure, a landing pad electrically connected to the first buried contact and disposed on the first bit line structure, a capacitor structure electrically connected to the landing pad and disposed on the landing pad, and a pair of inner extension portions disposed within the interface region and connected to a first surface of the first bit line structure and a second surface of the second bit line structure, respectively. The first surface is adjacent to the second surface. The first bit line structure and the second bit line structure are spaced apart from each other by a first distance. The pair of inner extension portions are spaced apart from each other by a second distance less than the first distance. The first distance and the second distance are measured in the first horizontal direction.

### BRIEF DESCRIPTION OF DRAWINGS

The above and other aspects, features, and advantages of the present inventive concept will be more clearly understood from the following detailed description, taken in conjunction with the accompanying drawings, in which:

FIG. 1A is a plan view of a semiconductor device according to example embodiments;

FIG. 1B is a vertical cross-sectional view of the semiconductor device illustrated in FIG. 1A, taken along lines A-A′ and B-B′;

FIG. 1C is a vertical cross-sectional view of a portion of the semiconductor device illustrated in FIG. 1A, taken along line C-C′;

FIG. 2A is an enlarged view of a portion of the bit line structures illustrated in FIG. 1A;

FIG. 2B is a top view of bit line structures in accordance with an example embodiment;

FIGS. 3A, 4A, 5A, 6A, 7A, 8A, 9A, 10A and 11A are plan views sequentially illustrating a method of manufacturing a semiconductor device according to an example embodiment, and FIGS. 3B, 4B, 5B, 6B, 7B to 7C, 8B to 8C, 9B to 9C, 10B to 10C, 11B to 11C, and 12 are cross-sectional views sequentially illustrating the method of manufacturing the semiconductor device according to the example embodiment;

FIG. 13A is a plan view of a semiconductor device according to example embodiments;

FIG. 13B is a vertical cross-sectional view of the semiconductor device illustrated in FIG. 13A taken along lines A-A′ and B-B′;

FIG. 14A is an enlarged view of a portion of the bit line structures illustrated in FIG. 13A;

FIG. 14B is a top view of bit line structures in accordance with an example embodiment; and

FIGS. 15A, 16A, 17A, 18A, and 19A are plan views sequentially illustrating a method of manufacturing a semiconductor device according to an example embodiment; and

FIGS. 15B, 16B to 16C, 17B to 17C, 18B to 18C, 19B to 19C, and 20 are cross-sectional views sequentially illustrating the method of manufacturing the semiconductor device according to the example embodiment.

### DETAILED DESCRIPTION

Hereinafter, example embodiments will be described with reference to the accompanying drawings.

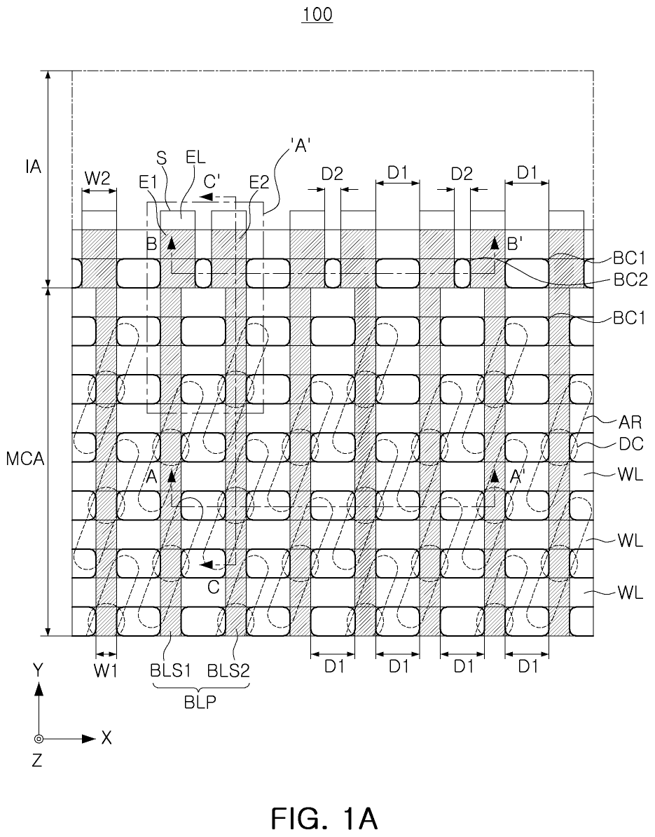

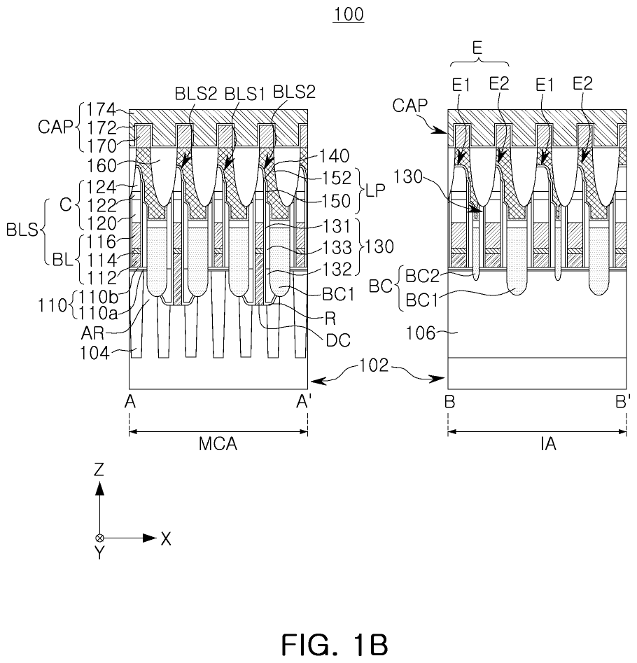

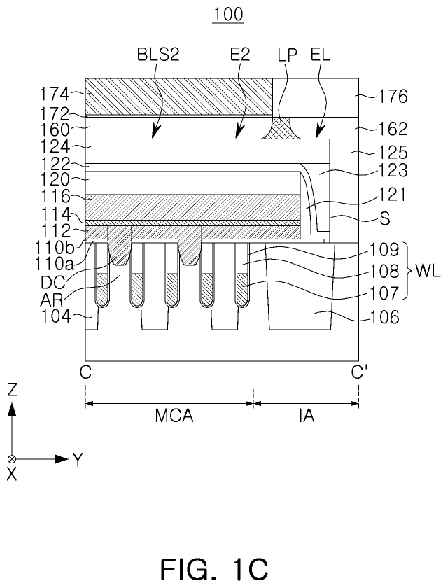

FIG. 1A is a plan view of a semiconductor device according to example embodiments. FIG. 1B is a vertical cross-sectional view of the semiconductor device illustrated in FIG. 1A, taken along lines A-A′ and B-B′. FIG. 1C is a vertical cross-sectional view of a portion of the semiconductor device illustrated in FIG. 1A, taken along line C-C′.

Referring to FIGS. 1A to 1C, a semiconductor device 100 according to an example embodiment may include a substrate 102, a gate structure WL, a buffer layer 110, a bit line structure BLS, a direct contact DC, a spacer structure 130, a silicide layer 140, a landing pad LP, and a capacitor structure CAP. The semiconductor device 100 may be applied to, for example, a cell array of Dynamic Random Access Memory (DRAM), but is not limited thereto.

The substrate 102 may include a cell region MCA and an interface region IA. The cell region MCA may refer to an area where a memory cell of a DRAM device is disposed. The interface region IA may refer to an area between a peripheral circuit area (not illustrated) where a row decoder and a sense amplifier are disposed and the cell region MCA. For example, the interface region IA may surround the cell region MCA.

The substrate 102 may include or may be formed of a semiconductor material, such as a group IV semiconductor, a group III-V compound semiconductor, and a group II-VI compound semiconductor. For example, the group IV semiconductor may include silicon, germanium, or silicon-germanium. The substrate 102 may be a silicon substrate, a silicon on insulator (SOI) substrate, a germanium substrate, a germanium on insulator (GOI) substrate, a silicon-germanium substrate, or a substrate including an epitaxial layer.

The substrate 102 may include an active region AR, a device isolation layer 104 and a region isolation layer 106. The device isolation layer 104 may be an insulating layer extending downward from the upper surface of the substrate 102 and may define the active region AR within the cell region MCA. For example, the active region AR may correspond to a portion of the upper surface of the substrate 102 surrounded by the device isolation layer 104. In a plan view, the active region AR may have a bar shape having a short axis and a long axis, and may extend in a direction between the X and Y-directions. The X and Y-directions may be referred to as first and second horizontal directions that are parallel to the upper surface of the substrate 102. The X-direction is different from the Y-direction.

The region isolation layer 106 may define an interface region IA. For example, in the cross-sectional view, a region where the region isolation layer 106 is disposed and a region facing the cell region MCA with respect to the region isolation layer 106 may be referred to as an interface region IA. In a plan view, the region isolation layer 106 may surround the cell region MCA. The region isolation layer 106 may be an insulating layer extending downward from the upper surface of the substrate 102. The region isolation layer 106 may electrically insulate the active region AR from a portion of the substrate 102 within the interface region IA. The device isolation layer 104 and the region isolation layer 106 may include or may be formed of silicon oxide, silicon nitride, silicon oxynitride, or a combination thereof. The device isolation layer 104 and the region isolation layer 106 may be formed of a single layer or a plurality of layers.

In a plan view, the gate structures WL may extend in the X-direction within the cell region MCA and may be spaced apart from each other in the Y-direction. Also, the gate structures WL may cross the active region AR. For example, two gate structures WL may cross with respect to one active region AR. In the cross-sectional view, the gate structures WL may be buried in the substrate 102, and for example, the gate structures WL may be disposed inside trenches formed in the substrate 102. Each of the gate structures WL may include a gate electrode 107, a gate capping layer 108, and a gate dielectric layer 109 disposed inside the trench. The gate dielectric layer 109 may be conformally formed on the inner wall of the trench. The gate electrode 107 may be disposed in a lower portion of the trench, and the gate capping layer 108 may be disposed on the gate electrode 107.

The gate electrode 107 may include or may be formed of a conductive material, for example, at least one of polycrystalline silicon (Si), titanium (Ti), titanium nitride (TiN), tantalum (Ta), tantalum nitride (TaN), tungsten (W), tungsten nitride (WN), and aluminum (Al). The gate capping layer 108 may include or may be formed of silicon nitride. The gate dielectric layer 109 may include or may be formed of silicon oxide or an insulating material having a high dielectric constant.

The buffer layer 110 may be disposed on the active region AR, the device isolation layer 104 and the gate structure WL. The buffer layer 110 may partially cover the region isolation layer 106 in the interface region IA. In an example embodiment, the buffer layer 110 may include a first buffer layer 110a and a second buffer layer 110b covering the first buffer layer 110a. The first buffer layer 110a may include or may be formed of silicon oxide, and the second buffer layer 110b may include or may be formed of silicon nitride. In some embodiments, the buffer layer 110 may have three or more layers or include different materials.

The bit line structure BLS may extend in the Y-direction while crossing the gate structures WL. The bit line structure BLS may be repeatedly arranged in the X-direction, and the bit line structures may be spaced apart from each other in the X-direction. The bit line structure BLS may have a bar shape extending in the Y-direction, may be disposed in the cell region MCA, and may further extend into the interface region IA. The bit line structure BLS may include a bit line BL and a bit line capping layer C on the bit line BL. For example, the bit line BL and the bit line capping layer C may extend from the cell region MCA into the interface region IA.

The bit line BL may include a first conductive layer 112, a second conductive layer 114, and a third conductive layer 116 that are sequentially stacked on the buffer layer 110. The first conductive layer 112 may include or may be formed of polysilicon. The second conductive layer 114 may include or may be formed of a metal-semiconductor compound. The metal-semiconductor compound may be, for example, a layer obtained by silicidation of a portion of the first conductive layer 112. For example, the metal-semiconductor compound may include cobalt silicide (CoSi), titanium silicide (TiSi), nickel silicide (NiSi), tungsten silicide (WSi), or other metal silicides, or may include ternary metal nitride such as TiSiN. The third conductive layer 116 may include or may be formed of metal such as titanium (Ti), tantalum (Ta), tungsten (W), and aluminum (Al). As illustrated in FIG. 1C, the bit line BL may further extend into the interface region IA. For example, the first conductive layer 112, the second conductive layer 114, and the third conductive layer 116 of the bit line BL may further extend into the interface region IA.

The bit line capping layer C may include a first capping layer 120, an insulating liner 122, and a second capping layer 124 disposed on the bit line BL. The side surface of the first capping layer 120 may be coplanar with the first conductive layer 112, the second conductive layer 114, and the third conductive layer 116. The first capping layer 120, the insulating liner 122, and the second capping layer 124 may include or may be formed of silicon oxide, silicon nitride, silicon oxynitride, or a combination thereof.

The semiconductor device 100 may further include an edge spacer 121, a first interlayer insulating layer 123, and a second interlayer insulating layer 125 disposed in the interface region IA. As illustrated in FIG. 1C, the first capping layer 120, the insulating liner 122 and the second capping layer 124 may further extend into the interface region IA. The edge spacer 121 may cover side surfaces of the first conductive layer 112, the second conductive layer 114, the third conductive layer 116, and the first capping layer 120. The insulating liner 122 may cover the edge spacer 121, the buffer layer 110, and the region isolation layer 106 in the interface region IA. The first interlayer insulating layer 123 may cover the insulating liner 122 in the interface region IA and may be disposed below the second capping layer 124. The second interlayer insulating layer 125 may cover side surfaces of the first interlayer insulating layer 123 and the second capping layer 124. In an example embodiment, the edge spacer 121, the first interlayer insulating layer 123, and the second interlayer insulating layer 125 may include or may be formed of silicon oxide.

The semiconductor device 100 may further include extension portions E disposed on both ends of the bit line structures BLS in the Y-direction in the interface region IA. In an example embodiment, the bit line structure BLS may include a first bit line structure BLS1 and a second bit line structure BLS2, and a first extension portion E1 and a second extension portion E2 may be disposed on both ends of the first bit line structure BLS1 and the second bit line structure BLS2 in the Y-direction, respectively, and may be connected thereto. For example, the bit line structure BLS may be repeatedly arranged in the X-direction and each bit line structure pair BLP may include or may be formed of a first bit line structure BLS1 and a second bit line structure BLS2. The semiconductor device 100 may further include an extension portion E that is repeatedly arranged in the X-direction and each extension portion pair may include or may be formed of a first extension portion E1 and a second extension portion E2. The first extension portion E1 and the second extension portion E2 may be disposed on an end portion of the first bit line structure BLS1 and an end portion of the second bit line structure BLS2, respectively. The end portion of the first line structure BLS1 may be disposed in the interface region IA, and the end portion of the second line structure BLS2 may be disposed in the interface region IA. For example, the first extension portion E1 and the first bit line structure BLS1 may be connected with each other. The second extension portion E2 and the second bit line structure BLS2 may connected with each other. Although only one ends of the bit line structures BLS in the Y-direction are illustrated in FIG. 1A, the extension portions E may be disposed on the other ends opposite to the one ends. The extension portions E may be materially continuous with the bit line structures BLS. For example, the extension portion E may have the same stacked structure as the bit line structures BLS. The extension portion E may include a first conductive layer 112, a second conductive layer 114, a third conductive layer 116, a first capping layer 120, an insulating liner 122, and a second capping layer 124, which may be extended from the bit line structure BLS.

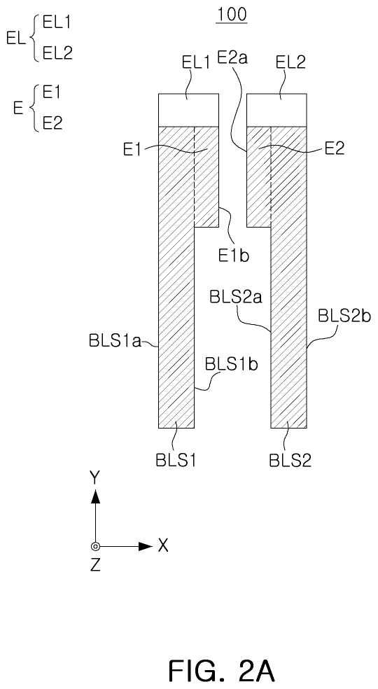

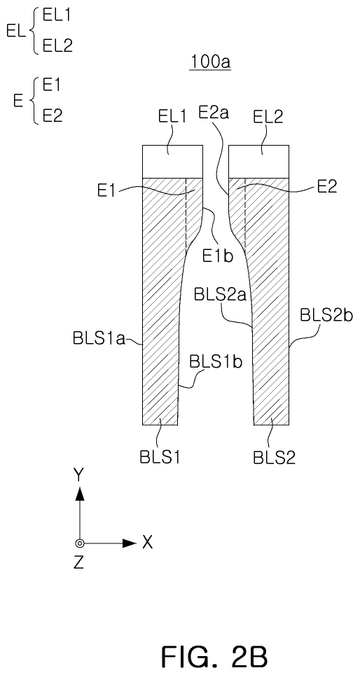

FIG. 2A is an enlarged view of a portion of the bit line structures illustrated in FIG. 1A. FIG. 2A is an enlarged view of area ‘A’ illustrated in FIG. 1A.

Referring to FIGS. 1A and 2A, the first bit line structure BLS1 and the second bit line structure BLS2 may be alternately disposed in the X-direction. The first bit line structure BLS1 and the second bit line structure BLS2 may be spaced apart from each other at regular intervals, for example, a first distance D1. In this case, ‘distance’ may refer to the shortest distance in the first horizontal direction (X-direction) between the adjacent bit line structures BLS1 and BLS2 or the distance between facing sides of the adjacent bit line structures BLS1 and BLS2 (i.e., a distance between a first side of the first bit line structure BLS1 and a second side of the second bit line structure BLS2, the first side being adjacent to the second side). The first bit line structure BLS1 and the second bit line structure BLS2 may have the same horizontal width, for example, the first width W1. The first bit line structure BLS1 and the second bit line structure BLS2 may form a bit line structure pair BLP (i.e., a pair of the first bit line structure BLS1 and the second bit line structure BLS2). The plurality of bit line structure pairs BLP may be spaced apart from each other in the X-direction, for example, by a first distance D1.

A distance between adjacent extension portions among the first extension portions E1 and the second extension portions E2 may have a first distance D1 and a second distance D2, and the first extension portions E1 and the second extension portions E2 may be disposed such that the first distance D1 and the second distance D2 are repeated. Distances between each first extension portion E1 and two second extension portions E2 adjacent thereto may be a first distance D1 and a second distance D2, respectively. For example, the distance between each first extension portion E1 and the second extension portion E2 adjacent to the left thereof may be the first distance D1, and the distance between each first extension portion E1 and the second extension portion E2 adjacent to the right thereof may be a second distance D2. The second distance D2 may be less than the first distance D1. In an embodiment, the extension portion E may be repeatedly arranged in the X-direction, and each extension portion pair may include or may be formed the first extension portion E1 and the second extension portion E2. The first extension portion E1 may be connected to the first bit line structure BLS1 and the second extension portion E2 may be connected to the second bit line structure BLS2. The plurality of extension portions pairs may be spaced apart from each other in the first distance D1, and in each extension pair, the first extension portion E1 and the second extension portion E2 may be spaced apart from each other in the second distance D2 less than the first distance D1. The connected structure of the first extension portion E1 and the first bit line structure BLS1 and the connected structure of the second extension portion E2 and the second bit line structure BLS2 may have the same horizontal width, for example, may have a second width W2. The second width W2 may be greater than the first width W1. Although not illustrated, bit line contacts electrically connected to the bit line structures BLS may be disposed on the first extension portions E1 and an upper surface of at least one of the first extension portions E1.

The first extension portion E1 and the second extension portion E2 may have a shape protruding from one sides of the first bit line structure BLS1 and the second bit line structure BLS2, respectively. For example, the first bit line structure BLS1 may include a first side surface BLS1a that extends in the Y-direction perpendicular to the X-direction and a second side surface BLS1b that extends in the Y-direction and that is opposite to the first side surface BLS1a. The first extension portion E1 may include a first side surface E1a that extends in the Y-direction perpendicular to the X-direction and a second side surface E1b. The second side surface E1b of the first extension portion E1 may extend in the Y-direction and may be opposite to the first side surface E1a. The first side surface E1a may be coplanar with the first side surface BLS1a, and the second side surface E1b may be spaced apart from the second side surface BLS1b in the X-direction. For example, a step may be present between the first extension portion E1 and the first bit line structure BLS1. The second bit line structure BLS2 may include a first side surface BLS2a that extends in the Y-direction perpendicular to the X-direction and a second side surface BLS2b opposite to the first side surface BLS2a. The second extension portion E2 may include a first side surface E2a that extends in the Y-direction perpendicular to the X-direction and a second side surface E2b opposite to the first side surface E2a. The first side surface BLS2a may face the second side surface BLS1b, and the first side surface E2a may face the second side surface E1b. The first side surface E2a may be spaced apart from the first side surface BLS2a in the X-direction, and the second side surface E2b may be coplanar with the second side surface BLS2b. For example, a step may be present between the first extension portion E1 and the first bit line structure BLS1. The extension portions E1 and E2 may not be aligned with the bit line structures BLS1 and BLS2 in the Y-direction. For example, the central axis of each extension portion E1 and E2 in the Y-direction may be offset from the central axis of the corresponding bit line structure BLS1 and BLS2 in the Y-direction. In this embodiment, the extension portion E may be arranged in a plurality, for example, two pitches. In this case, ‘pitch’ refers to the distance between centers in an arrangement direction, for example, the X-direction. One of the pitches of the extension portions E is smaller than the pitch of the bit line structures BLS, and the other may be larger than the pitch of the bit line structures BLS.

The semiconductor device 100 may further include edge insulating structures EL disposed on one ends of the first extension portion E1 and the second extension portion E2 in the Y-direction. The edge insulating structure (EL) may include the edge spacer 121, a portion of the insulating liner 122, and portions of the first interlayer insulating layer 123 and the second capping layer 124. The edge insulating structure EL may have a side surface S that extends in the X-direction perpendicular to the Y-direction, and the side surface S may contact the second interlayer insulating layer 125. The edge insulating structure EL may be formed together with the extension portions E in a process of forming the bit line structure BLS, which will be described later with reference to FIG. 12. In some embodiments, the edge insulating structures EL may include a plurality of first edge insulating structures EL1 and a plurality of second edge insulating structures EL2. Each of the first edge insulating structures EL1 may be connected to the first bit line structure BLS1 and the first extension portion E1. Each of the second edge insulating structures EL2 may be connected to the second bit line structure BLS2 and the second extension portion E2. Each first edge insulating structure EL1 may contact the first bit line structure BLS1 and the first extension portion E1, and each second edge insulating structure EL2 may contact the second bit line structure BLS2 and the second extension portion E2. The term “contact,” as used herein, refers to a direct connection (i.e., physical touching) unless the context indicates otherwise.

Referring back to FIGS. 1A to 1C, the direct contact DC may be disposed below the bit line structure BLS in a portion where the bit line structure BLS contacts the active region AR. For example, the direct contact DC may be disposed in a recess R formed in the upper surface of the substrate 102. In a plan view, the direct contact DC may contact the central portion of the active region AR. The upper surface of the direct contact DC may be positioned at the same level as the upper surface of the first conductive layer 112 and extend downward to contact the active region AR. The direct contact DC may electrically connect the active region AR to the bit line structure BLS. For example, the direct contact DC may pass through the first conductive layer 112 of the bit line structure BLS and be electrically connected to the second conductive layer 114 and the third conductive layer 116. The direct contact DC may include or may be formed of polysilicon.

The spacer structures 130 may be respectively disposed on opposite side surfaces of the bit line structures BLS and may extend in the Y-direction along the side surfaces of the bit line structures BLS. The spacer structure 130 may include a first spacer 131, a second spacer 132, and a third spacer 133 sequentially stacked on side surfaces of the bit line structures BLS. The first spacer 131 may be conformally disposed along side surfaces of the bit line structure BLS, the direct contact DC, and the recess R. The second spacer 132 may be disposed on the first spacer 131 and may fill the recess R. The third spacer 133 may cover the side surface of the first spacer 131 and the upper surface of the second spacer 132. The first spacer 131, the second spacer 132, and the third spacer 133 may include or may be formed of silicon oxide, silicon nitride, silicon oxynitride, or a combination thereof. The spacer structure 130 according to an example embodiment of the present inventive concept is an example, and the material and the number of layers are not limited thereto and may be variously changed.

The semiconductor device 100 may include buried contacts BC disposed between the bit line structures BLS and contacting the spacer structures 130. When viewed in a plan view, the buried contacts BC may be disposed between the bit line structures BLS and between the gate structures WL. Although the spacer structure 130 is omitted in the plan view, the buried contacts BC may be disposed between the spacer structures 130 to contact the spacer structures 130. The buried contacts BC may include a first buried contact BC1 and a second buried contact BC2. The first buried contact BC1 may be disposed between the first bit line structure BLS1 and the second bit line structure BLS2 in the cell region MCA. In the interface region IA, the first buried contacts BC1 and the second buried contacts BC2 may be alternately disposed between the first extension portions E1 and the second extension portions E2. For example, the second buried contact BC2 may be disposed between the first bit line structure BLS1 and the second bit line structure BLS2 constituting the bit line structure pair BLP, and the first buried contact BC1 may be disposed between adjacent bit line structure pairs BLP. For each first extension portion E1, the first buried contact BC1 may be disposed on the left side thereof, and the second buried contact BC2 may be disposed on the right side thereof.

In the cell region MCA, the first buried contact BC1 may extend into the substrate 102 to contact the active region AR and may be electrically connected to the active region AR. In the interface region IA, the first buried contact BC1 and the second buried contact BC2 may extend into the substrate 102 and contact the region isolation layer 106. The second buried contact BC2 may be smaller than the first buried contact BC1. For example, the second buried contact BC2 may have a smaller horizontal width than the first buried contact BC1. The height of the second buried contact BC2 may be less than the height of the first buried contact BC1. For example, the lower end of the second buried contact BC2 may be positioned at a higher level than the lower end of the first buried contact BC1. The upper surface of the second buried contact BC2 may be positioned at the same level as the upper surface of the first buried contact BC1, but the present inventive concept is not limited thereto. In an example embodiment, the first buried contact BC1 and the second buried contact BC2 disposed in the interface region IA may be dummy, but the present inventive concept is not limited thereto. The first buried contact BC1 and the second buried contact BC2 may be formed of a conductive material, for example, at least one of polycrystalline silicon (Si), titanium (Ti), titanium nitride (TiN), tantalum (Ta), tantalum nitride (TaN), tungsten (W), tungsten nitride (WN), and aluminum (Al).

The silicide layer 140 may be disposed on upper surfaces of the first buried contact BC1 and the second buried contact BC2. The landing pad LP may be disposed on the silicide layer 140, and may include a barrier layer 150 and a metal layer 152 that are disposed on the first bit line structure BLS1, the second bit line structure BLS2, the first extension portion E1, and the second extension portion E2. The silicide layer 140 may include or may be formed of cobalt silicide (CoSi), titanium silicide (TiSi), nickel silicide (NiSi), tungsten silicide (WSi), or other metal silicide. The barrier layer 150 may include or may be formed of a metal nitride, for example, at least one of titanium nitride (TiN), tantalum nitride (TaN), and tungsten nitride (WN). The metal layer 152 may include or may be formed of a conductive material, for example, at least one of titanium (Ti), tantalum (Ta), tungsten (W), and aluminum (Al).

The semiconductor device 100 may further include an insulating structure 160 disposed between the landing pads LP. The upper surface of the insulating structure 160 may be positioned at the same level as the upper surface of the landing pad LP, and the insulating structure 160 may extend downward to contact the bit line structures BLS and the extension portions E.

The capacitor structure CAP may be disposed on the landing pad LP and the insulating structure 160. The capacitor structure CAP may include a lower electrode 170, a capacitor dielectric layer 172 covering the lower electrode 170, and an upper electrode 174 covering the capacitor dielectric layer 172. The capacitor structure CAP may be electrically connected to the landing pad LP and the buried contact BC. The semiconductor device 100 may further include a third interlayer insulating layer 162 disposed on the same level as the landing pad LP and an upper insulating layer 176 disposed on the same level as the capacitor structure CAP in the interface region IA.

FIG. 2B is a top view of bit line structures according to an example embodiment.

Referring to FIG. 2B, in a semiconductor device 100a according to an example embodiment, s step may not be present between the first bit line structure BLS1 and the first extension portion E1 and between the second bit line structure BLS2 and the second extension portion E2. For example, the second side surface E1b of the first extension portion E1 may be curved, and the second side surface BLS1b may be continuous with the second side surface E1b. The first side surface BLS1a of the first bit line structure BLS1 and the first side surface E1a of the first extension portion E1 may be a plane perpendicular to the X-direction. The first side surface E2a of the second extension portion E2 may be curved. The first side surface BLS2a may be continuous with the first side surface E2a. The second side surface BLS2b of the second bit line structure BLS2 and the second side surface E2b of the second extension portion E2 may be a plane perpendicular to the X-direction. The first edge insulating structure EL1 may contact the first bit line structure BLS1 and the first extension portion E1, and the second edge insulating structure EL2 may contact the second bit line structure BLS2 and the second extension portion E2.

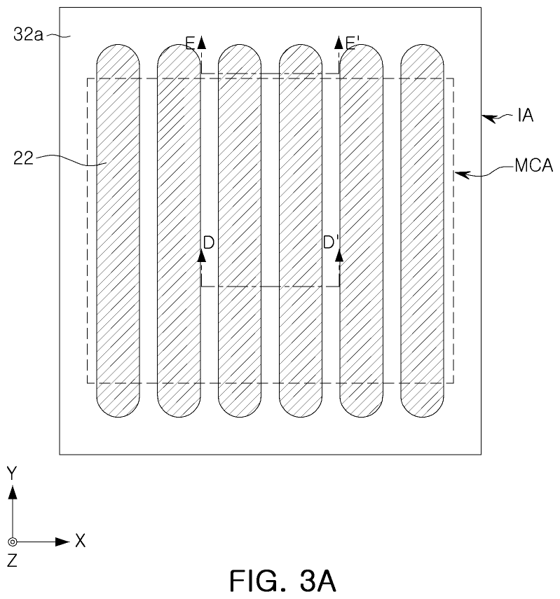

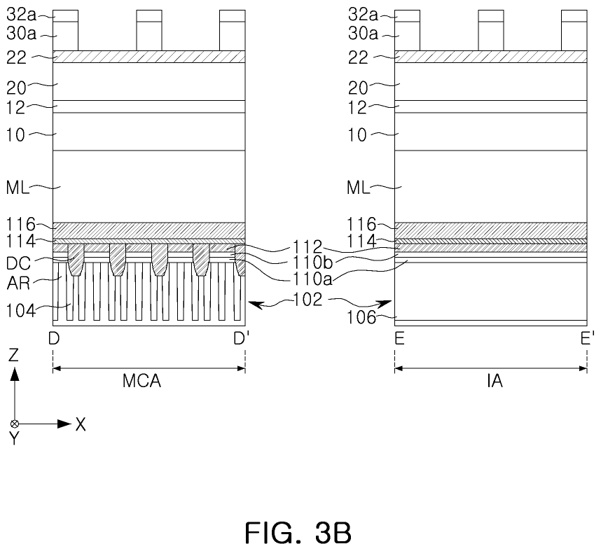

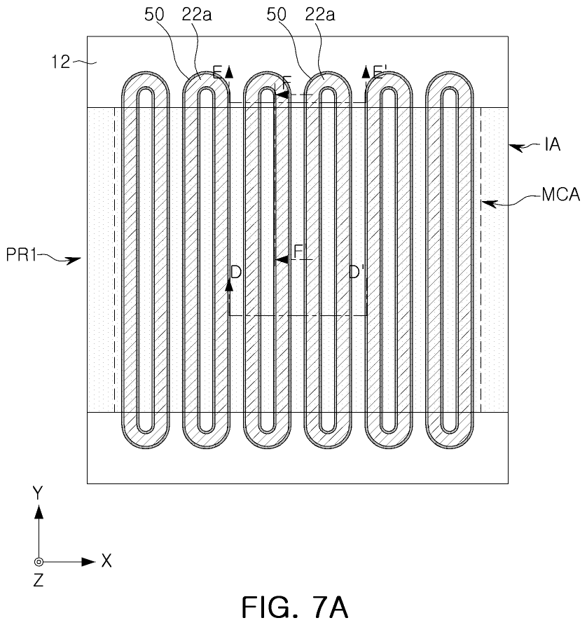

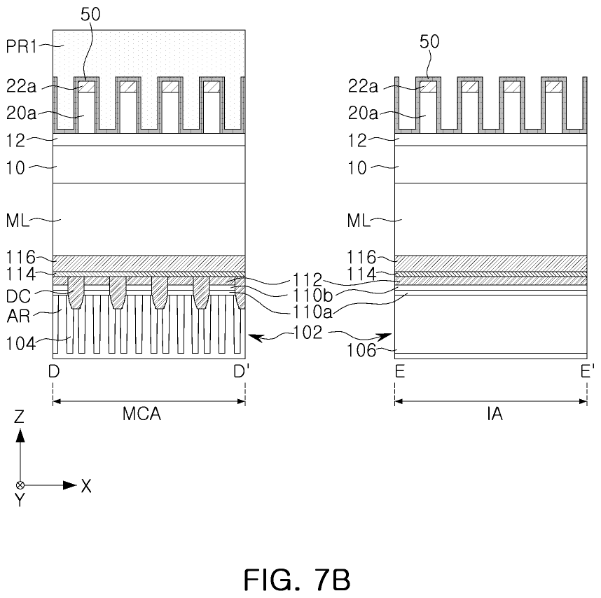

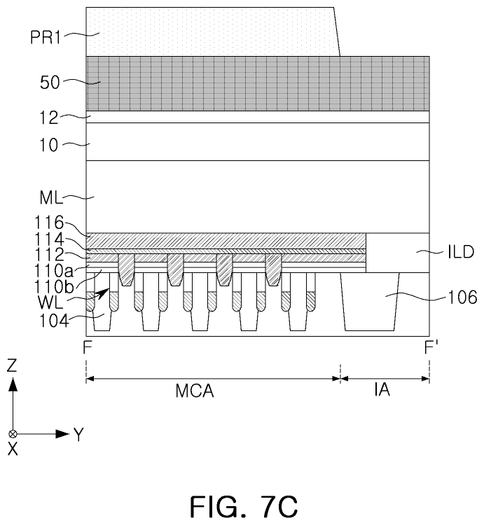

FIGS. 3A to 12 are plan views and cross-sectional views illustrating a method of manufacturing a semiconductor device according to an example embodiment according to a process sequence. In detail, FIGS. 3A, 4A, 5A, 6A, 7A, 8A, 9A, 10A, and 11A are plan views illustrating a method of manufacturing a semiconductor device corresponding to FIG. 1A. FIGS. 3B, 4B, 5B, 6B, 7B, 8B, 9B, 10B and 11B are vertical cross-sectional views taken along lines D-D′ and E-E′ of FIGS. 3A, 4A, 5A, 6A, 7A, 8A, 9A, 10A and 11A. FIGS. 7C, 8C, 9C, 10C, and 11C are vertical cross-sectional views taken along line F-F′ in FIGS. 7A, 8A, 9A, 10A, and 11A.

Referring to FIGS. 3A and 3B, a device isolation layer 104 and a region isolation layer 106 may be formed on the substrate 102. The substrate 102 may include a cell region MCA and an interface region IA. The interface region IA may surround the cell region MCA, and the interface region IA may be disposed between the cell region MCA and a peripheral circuit area (not illustrated). The device isolation layer 104 may be disposed in the cell region MCA of the substrate 102, and the region isolation layer 106 may be disposed in the interface region IA of the substrate 102.

The device isolation layer 104 and the region isolation layer 106 may be formed by forming a trench in the upper surface of the substrate 102, filling the trench with an insulating material, and performing a planarization process of etching the substrate 102 and the insulating material. The device isolation layer 104 may define active regions AR in the cell region MCA. For example, the active regions AR may correspond to portions of the upper surface of the substrate 102 surrounded by the device isolation layer 104. When viewed in a plan view, the active regions AR may have a bar shape having short and long axes, and may be spaced apart from each other. The device isolation layer 104 may include or may be formed of silicon oxide, silicon nitride, silicon oxynitride, or a combination thereof. The device isolation layer 104 may be composed of a single layer or multiple layers.

The region isolation layer 106 may define an interface region IA. For example, in the cross-sectional view, a region where the region isolation layer 106 is disposed and a region facing the cell region MCA with respect to the region isolation layer 106 may be referred to as the interface region IA. In a plan view, the region isolation layer 106 may surround the cell region MCA, and for example, the region isolation layer 106 may extend in the X-direction and the Y-direction. The region isolation layer 106 may be an insulating layer extending downward from the upper surface of the substrate 102. The region isolation layer 106 may include or may be formed of silicon oxide, silicon nitride, silicon oxynitride, or a combination thereof. The region isolation layer 106 may be composed of a single layer or multiple layers.

Although not illustrated, gate structures WL crossing the device isolation layers 104 and extending in the X-direction may be formed in the substrate 102. The gate structures WL may be formed by forming trenches extending in the X-direction in the substrate 102, forming a dielectric material on the inner walls of the trenches, forming a conductive material in lower portions of the trenches, and forming a capping material on the conductive material.

On the substrate 102, the first buffer layer 110a, the second buffer layer 110b, the first conductive layer 112, the direct contact DC, the second conductive layer 114, the third conductive layer 116, and the mold layer ML may be formed sequentially. The first buffer layer 110a and the second buffer layer 110b may be conformally formed on the substrate 102 by a chemical vapor deposition (CVD) process or an atomic layer deposition (ALD) process. The first buffer layer 110a and the second buffer layer 110b may include or may be formed of silicon oxide, silicon nitride, silicon oxynitride, or a combination thereof. For example, the first buffer layer 110a may include or may be formed of silicon oxide, and the second buffer layer 110b may include or may be formed of silicon nitride.

The first conductive layer 112 may be formed on the second buffer layer 110b. After forming the first conductive layer 112, an opening is formed by partially etching the first conductive layer 112, the second buffer layer 110b, the first buffer layer 110a, and the active region AR, and the opening is filled with a conductive material, thereby forming a direct contact DC. Upper surfaces of the first conductive layer 112 and the direct contact DC may be coplanar with each other. The first conductive layer 112 and the direct contact DC may include or may be formed of polysilicon. The second conductive layer 114 may include or may be formed of metal silicide. The third conductive layer 116 may include or may be formed of metal.

As illustrated in FIG. 7C to be described later, the first buffer layer 110a, the second buffer layer 110b, the first conductive layer 112, the second conductive layer 114, and the third conductive layer 116 may be cut within the interface region IA so as not to extend to a peripheral circuit area (not illustrated). In some embodiments, the first buffer layer 110a and the second buffer layer 110b may extend further toward the interface region IA than the first conductive layer 112, the second conductive layer 114, and the third conductive layer 116.

A mold layer ML may be formed on the third conductive layer 116. The mold layer ML may be disposed over the cell region MCA and the interface region IA. The mold layer ML may be formed of one layer, but is not limited thereto. In some embodiments, the mold layer ML may be formed of a plurality of layers disposed on the third conductive layer 116 as illustrated in FIG. 1C. The mold layer ML may include a first capping layer 120, an insulating liner 122 and a second capping layer 124. The mold layer ML may further include an edge insulating structure EL. The edge insulating structure EL may include an edge spacer 121, a portion of the insulating liner 122 covering the edge spacer 121, a first interlayer insulating layer 123, and a portion of the second capping layer 124 covering the first interlayer insulating layer 123.

A bit line mask layer 10, an etch stop layer 12, a first mask layer 20, a first etch stop layer 22, a second mask pattern 30a, and a second etch stop pattern 32a may be sequentially formed on the mold layer ML in the cell region MCA and the interface region IA. The second mask pattern 30a and the second etch stop pattern 32a may be formed by forming a mask layer and an etch stop layer on the first etch stop layer 22 and then etching the mask layer and the etch stop layer in a bar shape using a photoresist. The second mask pattern 30a does not completely cover the first etch stop layer 22, and an upper surface of the first etch stop layer 22 may be partially exposed.

The bit line mask layer 10, the first mask layer 20, and the second mask pattern 30a may include or may be formed of a material having etch selectivity with respect to the mold layer ML, and for example, may include or may be formed of an amorphous carbon layer (ACL). The etch stop layer 12, the first etch stop layer 22, and the second etch stop pattern 32a may include or may be formed of a material having etch selectivity with respect to the bit line mask layer 10, the first mask layer 20, and the second mask pattern 30a, and for example, may include or may be formed of silicon oxynitride (SiON).

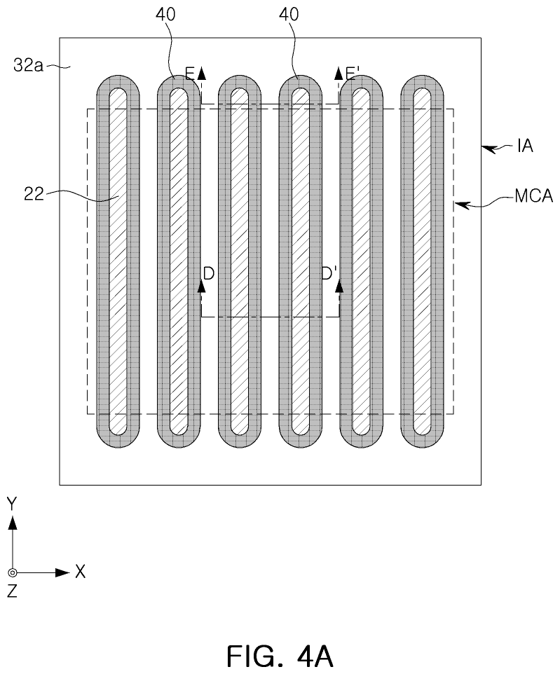

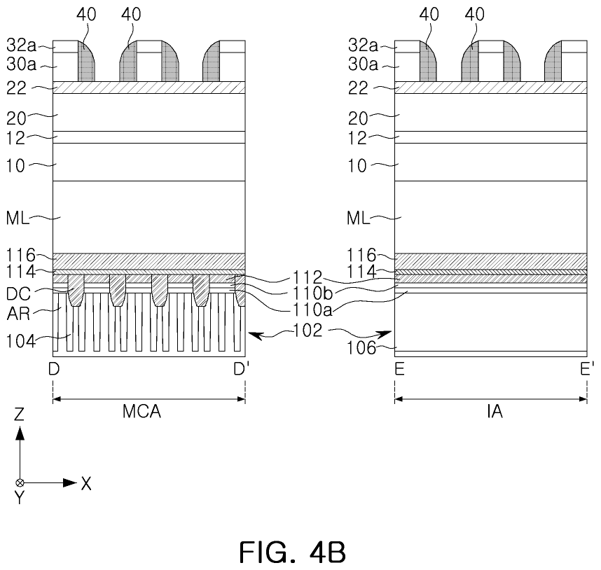

Referring to FIGS. 4A and 4B, spacer patterns 40 may be formed on side surfaces of the second mask pattern 30a and the second etch stop pattern 32a. For example, after an insulating material is conformally formed on the first etch stop layer 22, the second mask pattern 30a, and the second etch stop pattern 32a by a method such as CVD and ALD, an anisotropic etching process may be performed on the insulating material. An upper surface of the second etch stop pattern 32a may be exposed by the etching process, and the spacer patterns 40 may be formed by leaving portions of the insulating material on the side surfaces of the second mask pattern 30a and the second etch stop pattern 32a. The spacer pattern 40 may partially cover the first etch stop layer 22.

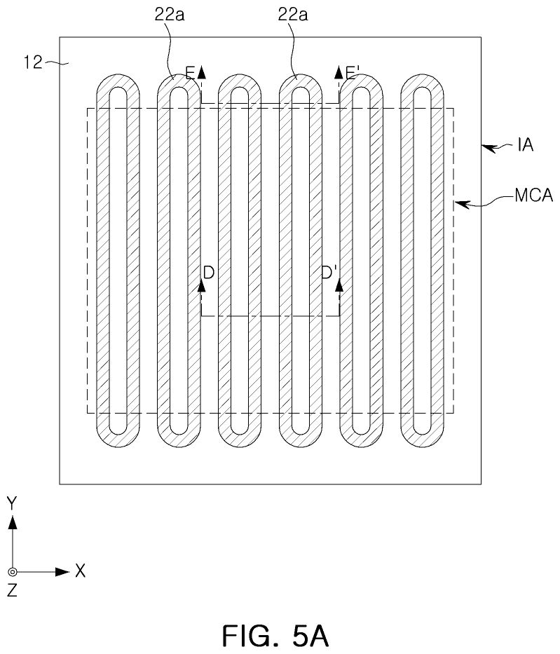

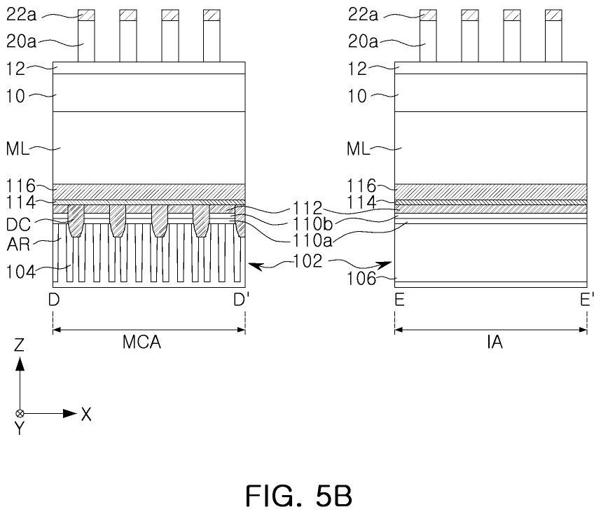

Referring to FIGS. 5A and 5B, a first mask pattern 20a and a first etch stop pattern 22a may be formed by etching the first mask layer 20 and the second etch stop layer 12. The first mask pattern 20a and the first etch stop pattern 22a may be formed using double patterning technology (DPT). For example, the second mask pattern 30a and the second etch stop pattern 32a are removed, and an etching process is performed by using the spacer pattern 40 as an etching mask, thereby patterning the first mask layer 20 and the first etch stop layer 22. The first mask pattern 20a and the first etch stop pattern 22a may extend along the spacer pattern 40, and then the spacer pattern 40 may be removed. In a plan view, the first mask pattern 20a and the first etch stop pattern 22a may have a closed loop shape or a shape in which a pair of rod-shaped structures extending in the Y-direction are connected to each other on both ends.

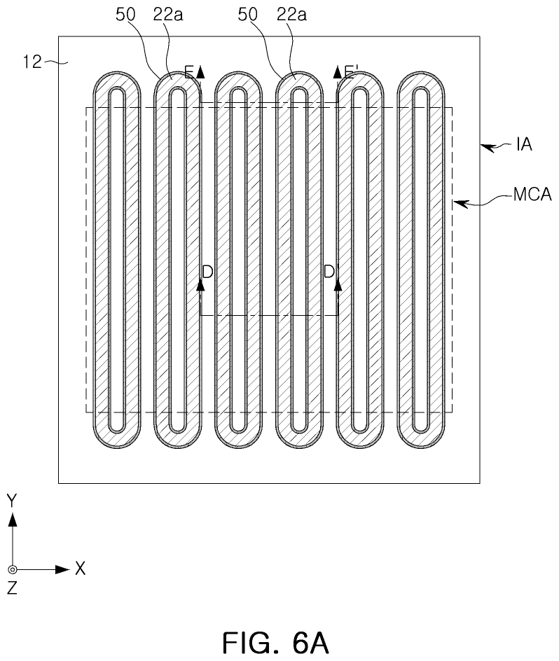

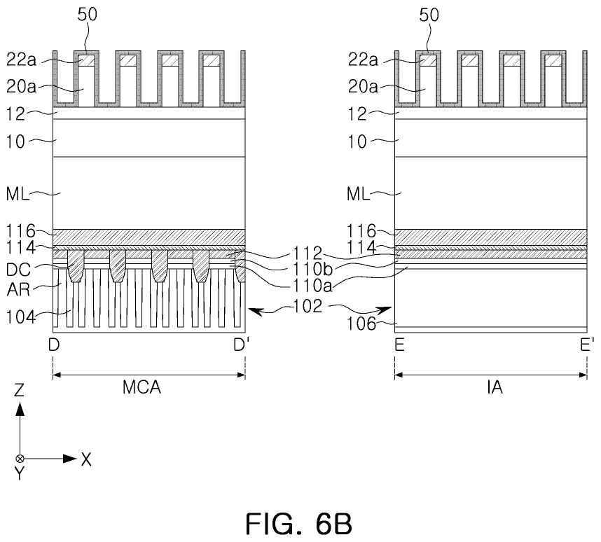

Referring to FIGS. 6A and 6B, a first spacer material layer 50 may be formed to cover the etch stop layer 12, the first mask pattern 20a and the first etch stop pattern 22a. The first spacer material layer 50 may be conformally formed by a method such as CVD and ALD, and may include or may be formed of silicon oxide. For convenience of explanation, FIG. 6A illustrates that the first spacer material layer 50 is disposed only on the side surface of the first etch stop pattern 22a, but the first spacer material layer 50 may cover the resultant structure of FIGS. 5A and 5B in the cell region MCA. and in the interface region IA.

Referring to FIGS. 7A to 7C, a first photoresist PR1 may be formed in the cell region MCA. The first photoresist PR1 may be formed by coating the photosensitive material to cover the cell region MCA and the interface region IA and then performing an exposure process and a development process to partially remove the photoreceptor material. The first photoresist PR1 may cover the cell region MCA and expose the interface region IA.

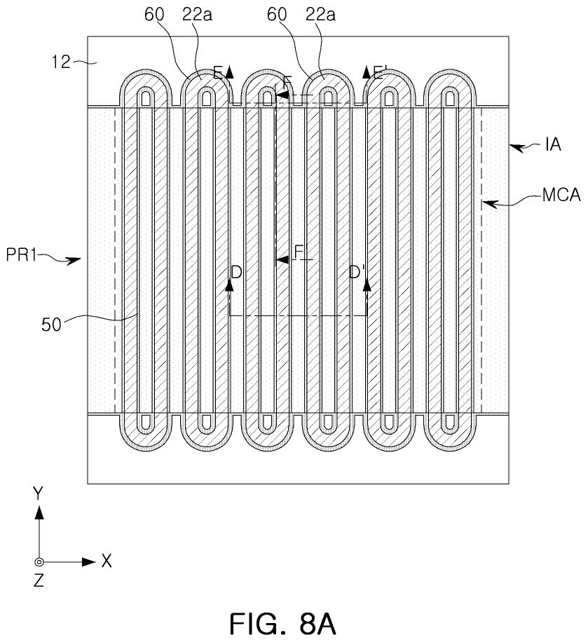

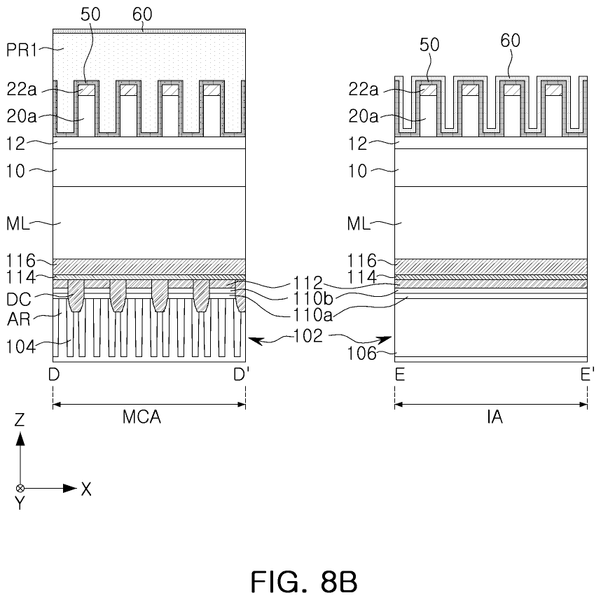

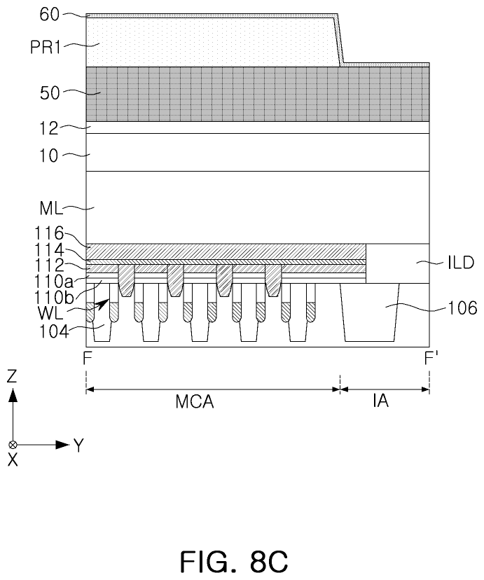

Referring to FIGS. 8A to 8C, a second spacer material layer 60 may be formed to cover the first photoresist PR1 and the first spacer material layer 50. The second spacer material layer 60 may be conformally formed by a method such as CVD and ALD, and may include or may be formed of silicon oxide. For convenience of description, although FIG. 8A illustrates that the second spacer material layer 60 is disposed only on the side surface of the first etch stop pattern 22a, the second spacer material layer 60 may cover the resulting structure of FIGS. 7A to 7C in the cell region MCA and the interface region IA.

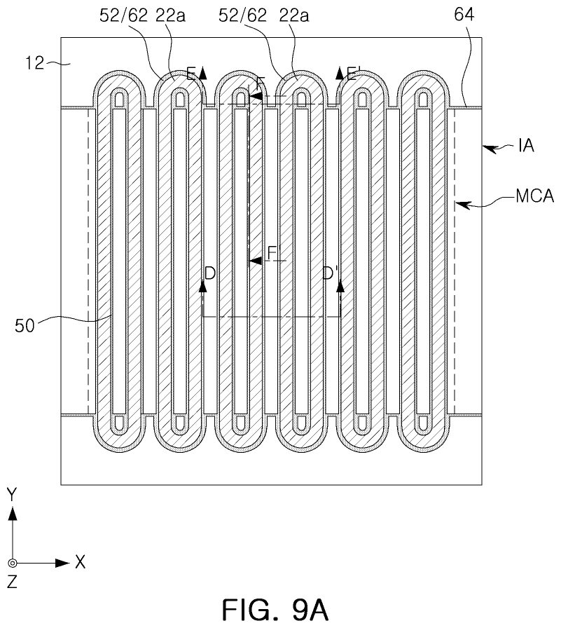

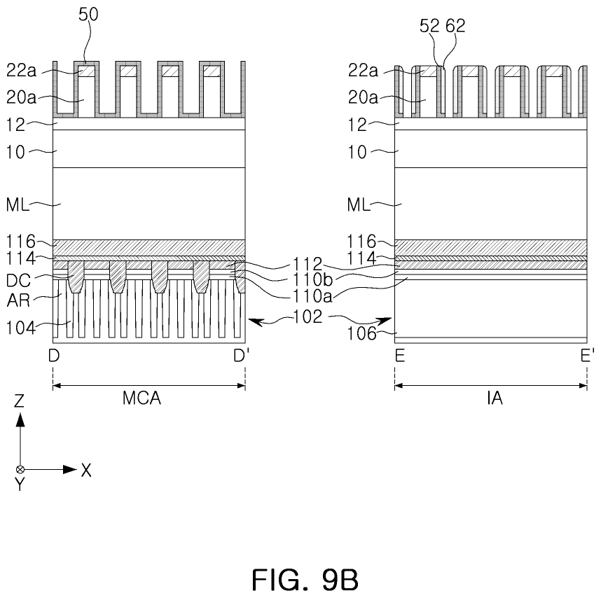

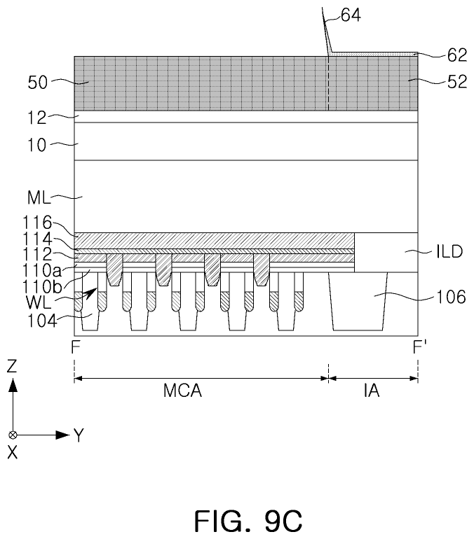

FIGS. 9A to 9C, the first spacer material layer 50 and the second spacer material layer 60 may be etched in the interface region IA to form the first spacer pattern 52 and the second spacer pattern 62. The first spacer pattern 52 may cover side surfaces of the first mask pattern 20a and the first etch stop pattern 22a, and may extend in a horizontal direction along side surfaces of the first mask pattern 20a and the first etch stop pattern 22a within the interface region IA. The second spacer pattern 62 may cover the side surface of the first spacer pattern 52, and may extend in a horizontal direction along the side surface of the first spacer pattern 52 within the interface region IA.

A portion of the second spacer material layer 60 covering the first photoresist PR1 may be removed by the etching process. In an example embodiment, the second spacer material layer 60 may not be entirely removed, and for example, a portion of the second spacer material layer 60 covering the side surface of the first photoresist PR1 may remain and may be referred to as a remaining portion 64. The remaining portion 64 may extend in the X-direction and may have a straight line shape when viewed in a plan view. In some embodiments, the remaining portion 64 may not be generated by the etching process, and a portion of the second spacer material layer 60 covering the first photoresist PR1 may be completely removed.

Then, the first photoresist PR1 may be removed by an ashing and stripping process. Since the first spacer material layer 50 is covered by the first photoresist PR1 in the cell region MCA during the etching process, a portion of the first spacer material layer 50 in the cell region MCA may not be etched by the etching process.

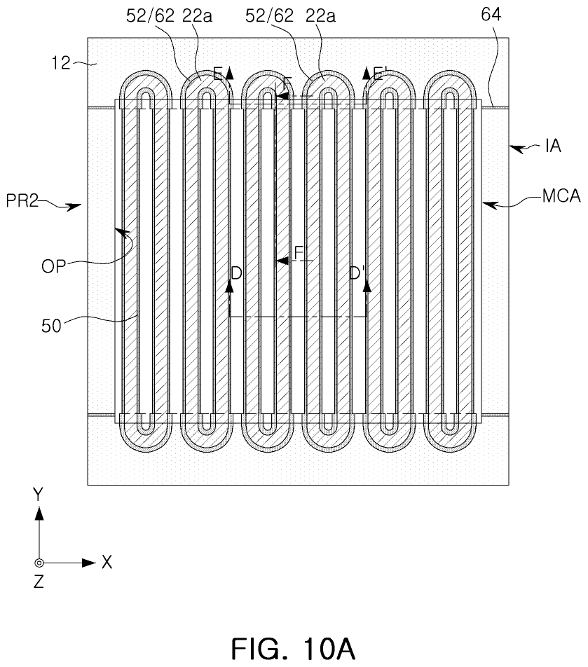

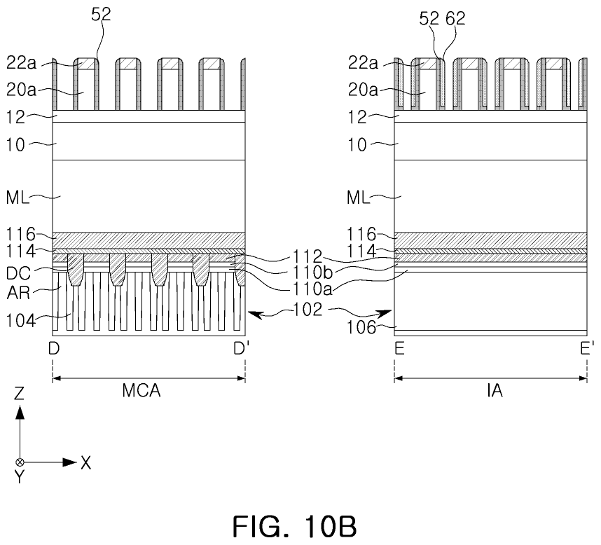

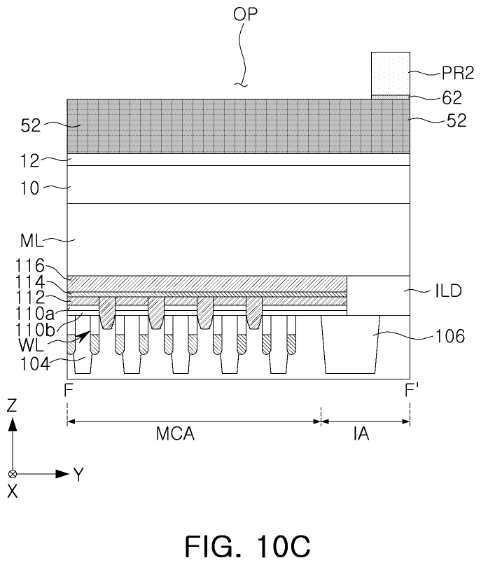

Referring to FIGS. 10A to 10C, a second photoresist PR2 may be formed in the interface region IA. The second photoresist PR2 may expose a portion of the interface region IA and the cell region MCA. For example, the second photoresist PR2 may include an opening OP. The opening OP may expose the cell region MCA and may further extend in the Y-direction from the cell region MCA toward the interface region IA to expose a portion of the interface region IA. The opening OP may partially expose the first spacer pattern 52, the second spacer pattern 62, and the remaining portion 64.

After the second photoresist PR2 is formed, the first spacer material layer 50 in the cell region MCA may be etched by an etching process to form the first spacer pattern 52. The first spacer pattern 52 and the second spacer pattern 62 may be further etched in the interface region IA by the etching process to reduce the horizontal width, but the present inventive concept is not limited thereto.

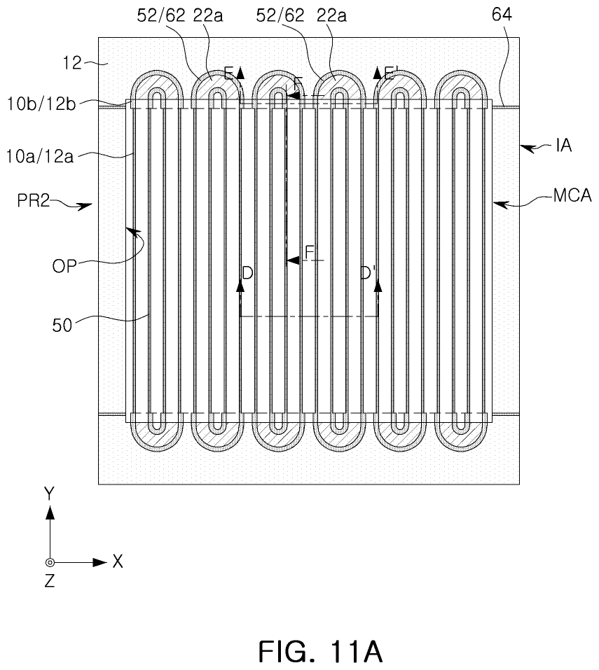

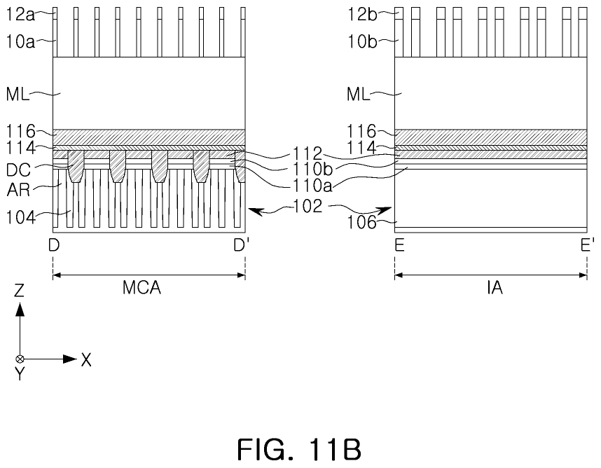

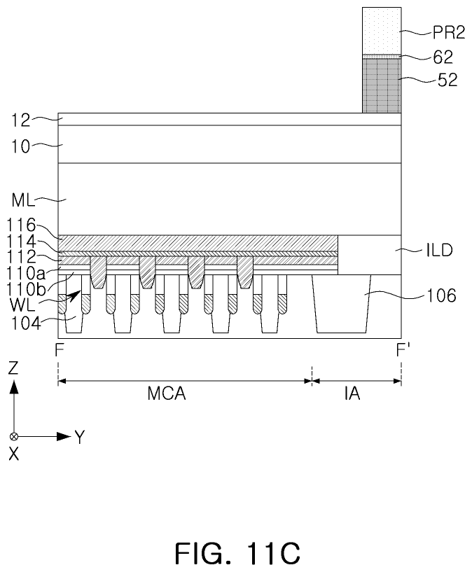

Referring to FIGS. 11A to 11C, the bit line mask layer 10 and the etch stop layer 12 are etched to form an internal mask pattern 10a on the mold layer ML, an internal etch stop pattern 12a on the internal mask pattern 10a, an external mask pattern 10b and an external etch stop pattern 12b on the external mask pattern 10b. The etching process may be performed using DPT. For example, the first mask pattern 20a and the first etch stop pattern 22a are removed, and the bit line mask layer 10 and the etch stop layer 12 may be patterned by an etching process using the first spacer pattern 52 and the second spacer pattern 62 as an etch mask. The internal mask pattern 10a and the internal etch stop pattern 12a may be formed in the cell region MCA and may extend along the first spacer pattern 52. The external mask pattern 10b and the external etch stop pattern 12b may be formed in the interface region IA and may extend along the first spacer pattern 52 and the second spacer pattern 62. Afterwards, the first spacer pattern 52 and the second spacer pattern 62 may be removed. When viewed in a plan view, the internal mask pattern 10a and the inner etch stop pattern 12a may have a line-and-space shape, and for example, may have a rod shape extending in the Y-direction. When viewed in a plan view of FIG. 11A, a stacked structure of the external mask pattern 10b and the external etch stop pattern 12b may be disposed on opposite ends of a stacked structure of the internal mask pattern 10a and the internal etch stop pattern 12a. When viewed in a cross-sectional view of FIG. 11B, a cross-sectional area of the stacked structure of the external mask pattern 10b and the external etch stop pattern 12b may be larger than a cross-sectional area of the stacked structure of the internal mask pattern 10a and the internal etch stop pattern 12a.

FIG. 12 is a vertical cross-sectional view corresponding to FIG. 1B and may correspond to a portion of the cross-sectional views illustrated in FIG. 11B. For convenience of descriptions, the scale of some components of FIG. 12 may be different from that of FIG. 11B.

Referring to FIG. 12, by an etching process using the internal mask pattern 10a and the inner etch stop pattern 12a as an etch mask in the cell region MCA, the first conductive layer 112, the direct contact DC, the second conductive layer 114, the third conductive layer 116, and the mold layer ML may be etched. The etched first conductive layer 112, direct contact DC, second conductive layer 114 and third conductive layer 116 may form a bit line BL. The mold layer ML disposed on the bit line BL may include a first capping layer 120, an insulating liner 122, and a second capping layer 124 that are sequentially stacked, which are etched to form the bit line capping layer (C). The bit line BL and the bit line capping layer C may form a bit line structure BLS.

The bit line structure BLS may include a first bit line structure BLS1 and a second bit line structure BLS2. The first bit line structure BLS1 and the second bit line structure BLS2 may be alternately disposed in the X-direction and may extend in the Y-direction. The first bit line structure BLS1 and the second bit line structure BLS2 may be spaced apart from each other at regular intervals, and for example, may be spaced apart from each other by a first distance D1. The first bit line structure BLS1 and the second bit line structure BLS2 may have the same horizontal width, and for example, may have a first width W1. The first buffer layer 110a, the second buffer layer 110b, and the substrate 102 may be etched, and a recess R may be formed at an upper surface of the substrate 102. The recess R may expose a side surface of the direct contact DC.

The etching process may be performed on an area exposed by the second photoresist PR2 within the interface region IA. By an etching process using the external mask pattern 10b and the external etch stop pattern 12b as an etching mask, the first conductive layer 112, the second conductive layer 114, the third conductive layer 116, and the mold layer ML may be etched. The etched first conductive layer 112, second conductive layer 114, third conductive layer 116, first capping layer 120, insulating liner 122 and second capping layer 124 may form an extension portion E. When the extension portion E is formed, the edge insulating structure EL including the edge spacer 121, a portion of the insulating liner 122, the first interlayer insulating layer 123, and a portion of the second capping layer 124 may be formed together (see FIG. 1C).

The extension portion E may include a first extension portion E1 and a second extension portion E2. The first extension portion E1 and the second extension portion E2 may be formed on opposite ends of the first bit line structure BLS1 and the second bit line structure BLS2 in the Y-direction, respectively. The first extension portion E1 and the second extension portion E2 may be alternately disposed in the X-direction and may extend in the Y-direction. As described above, the distance between adjacent extension portions among the first extension portions E1 and the second extension portions E2 may have a first distance D1 and a second distance D2, and the first extension portions E1 and the second extension portions E2 may be disposed such that the first distance D1 and the second distance D2 are repeated. The first extension portion E1 and the second extension portion E2 may have the same horizontal width. In some embodiments, a width of the connected structure of the first bit line structure BLS1 and the first extension portion E1 may be a second width W2 that is greater than the first width W1.

The second photoresist PR2 on the interface region IA and the second spacer pattern 62, the first spacer pattern 52, the etch stop layer 12, and the bit line mask layer 10 covered thereby may be removed.

As illustrated in FIGS. 11A and 11B, by forming the horizontal width of the external mask pattern 10b and the external etch stop pattern 12b wider than the horizontal width of the internal mask pattern 10a and the internal etch stop pattern 12a, horizontal widths of the first extension portion E1 and the second extension portion E2 may be greater than horizontal widths of the first bit line structure BLS1 and the second bit line structure BLS2. Therefore, in the process of etching the first to third conductive layers 112, 114, and 116 and the mold layer ML, the first to third conductive layers 112, 114, and 116 may be prevented from being thinned and necked, which may cause a process defect such as disconnection of at least one of the first to third conductive layers 112, 114, and 116. Therefore, the reliability of the device may be improved. Spaces in which bit line contacts (not illustrated) disposed on the first extension portion E1 and the second extension portion E2 are to be formed may be secured.

Referring back to FIGS. 1A to 1C, a second interlayer insulating layer 125 covering the side surface S of the edge insulating structure EL may be formed. Subsequently, a spacer structure 130 including a first spacer 131, a second spacer 132, and a third spacer 133 may be formed in the cell region MCA and the interface region IA. In the cell region MCA, the spacer structure 130 may cover side surfaces of the first bit line structure BLS1 and the second bit line structure BLS2. For example, the first spacer 131 may be formed to cover side surfaces of the first bit line structure BLS1, the second bit line structure BLS2, and the recess R, and the second spacer 132 may be formed to fill the inside of the recess R. The third spacer 133 may be formed on the second buffer layer 110b and the second spacer 132 to cover side surfaces of the first spacer 131. Within the interface region IA, the spacer structure 130 may cover side surfaces of the first extension portion E1 and the second extension portion E2.

Buried contacts BC may be formed on side surfaces of the bit line structure BLS and the extension portion E. The buried contacts BC may be formed by forming a trench extending in the Y-direction between the bit line structure BLS and the extension portion E, depositing a conductive material in the trench, and etching back the conductive material. The buried contacts BC are spaced apart from each other in the Y-direction, and fence insulation layers (not illustrated) may be disposed between the buried contacts BC. The buried contacts BC may extend into the substrate 102. For example, lower ends of the buried contacts BC may be positioned at a level lower than the upper surface of the substrate 102. The buried contacts BC may include or may be formed of polysilicon.

The buried contacts BC may include a first buried contact BC1 and a second buried contact BC2. A first buried contact BC1 may be disposed between the first bit line structure BLS1 and the second bit line structure BLS2 in the cell region MCA. In the interface region IA, first buried contacts BC1 and second buried contacts BC2 may be alternately disposed between the first extension portions E1 and the second extension portions E2. The second buried contact BC2 may be smaller than the first buried contact BC1. For example, the second buried contact BC2 may have a smaller horizontal width than the first buried contact BC1. A lower end of the second buried contact may be positioned at a higher level than a lower end of the first buried contact BC1.

Then, a barrier layer 150 and a metal layer 152 may be formed on the bit line structure BLS, the extension portion E, the spacer structure 130 and the buried contact BC. A landing pad LP and an insulating structure 160 may be formed by patterning the barrier layer 150 and the metal layer 152 and filling the same with an insulating material. A silicide layer 140 may be formed between the buried contact BC and the landing pad LP. As illustrated in FIG. 1B, a landing pad LP may also be disposed in the interface region IA, and in an example embodiment, the landing pad LP in the interface region IA may be a dummy pad. As illustrated in FIG. 1C, the landing pad LP may have a dam structure within the interface region IA. A third interlayer insulating layer 162 may be formed on the same level as the dam structure in the interface region IA.

A capacitor structure CAP including a lower electrode 170, a capacitor dielectric layer 172, and an upper electrode 174 may be formed on the landing pad LP in the cell region MCA. The capacitor structure CAP may also be formed in the interface region IA, and in an example embodiment, the capacitor structure CAP in the interface region IA may be a dummy capacitor. In addition, an upper insulating layer 176 may be formed at the same level as the capacitor structure CAP in the interface region IA. As a result, the semiconductor device 100 of FIGS. 1A to 1C may be manufactured.

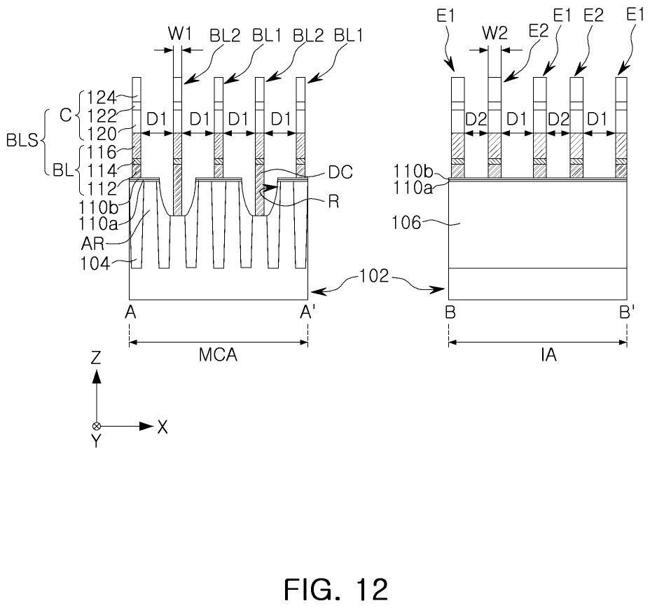

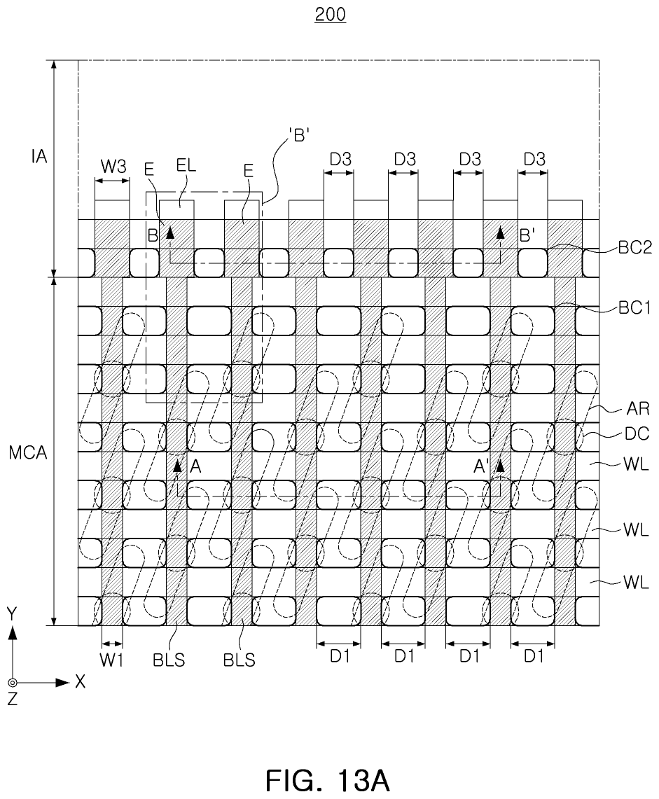

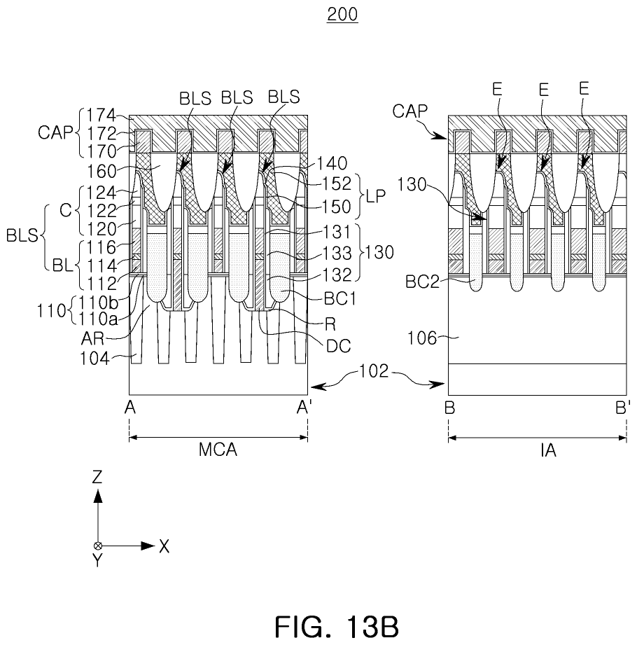

FIG. 13A is a plan view of a semiconductor device according to example embodiments. FIG. 13B is a vertical cross-sectional view of the semiconductor device illustrated in FIG. 13A, taken along lines A-A′ and B-B′.

Referring to FIGS. 13A and 13B, unlike the semiconductor device 100 illustrated in FIGS. 1A and 1B, a semiconductor device 200 may include a bit line structure BLS and an extension portion pair E that may be disposed on opposite side surfaces, in the X-direction, of the bit line structure BLS. The connected structure of the bit line structure and the extension portion pair E may be spaced apart from each other at a regular interval in the X-direction. For example, the connected structure of the bit line structure BLS and the extension portion pair E may be repeatedly arranged in the X-direction, and the plurality of connected structures may be spaced apart from each other by a third distance D3 less than the first distance D1. The connected structure of the bit line structure BLS and the extension portion pair E may have a third width W3 greater than the first width W1.

FIG. 14A is an enlarged view of a portion of the bit line structures illustrated in FIG. 13A. FIG. 14A is an enlarged view of area ‘B’ illustrated in FIG. 13A.

Referring to FIGS. 13A and 14A, the extension portion pair E may include or may be formed of a first extension portion E1 and a second extension portion E2 that are connected to opposite side surfaces BLSa and BLSb, in the X-direction, of the bit line structure BLS, respectively. For example, the bit line structure BLS may include a first side surface BLSa perpendicular to the X-direction and a second side surface BLSb opposite to the first side surface BLSa. The first extension portion E1 may be connected to a first side surface BLSa, and the second extension portion E2 may be connected to a second side surface BLSb. The first extension portion E1 may include a first side surface Ea extending in the Y-direction perpendicular to the X-direction. The second extension portion E2 may include a second side surface Eb that is opposite to the first side surface Ea. The first side surface E1a may be spaced apart from the first side surface BLS1a in the X-direction, and for example, a step may be present between the first extension portion E1 and the bit line structure BLS. The extension portion pair E may be aligned with the bit line structure BLS in the Y-direction. For example, a central axis of the extension portion pair E in the Y-direction may be aligned with a central axis of the bit line structure BLS in the Y-direction. The first extension portion E1 and the second extension portion E2 may be symmetric with reference to the bit line structure BLS, and thus the central axis of the extension portion pair E in the Y-direction may correspond to or may be aligned with the central axis of the bit line structure BLS in the Y-direction. Accordingly, in this embodiment, the extension portion pair E may be arranged at the same pitch as the bit line structures BLS. In some embodiments, an edge insulating structure EL may be connected to the bit line structure BLS, the first extension portion E1, and the second extension portion E2. The edge insulating structure EL may contact the bit line structure BLS, and the first extension portion E1 and the second extension portion E2 that are connected to the opposite side surfaces BLSa and BLSb of the bit line structure BLS1.

Referring back to FIGS. 13A and 13B, the semiconductor device 200 may further include a first buried contact BC1 disposed between the bit line structures BLS, and a second buried contact BC2 disposed between the extension portions E. The first buried contact BC1 may have the same structure as the buried contact BC illustrated in FIG. 1B, may be disposed in the cell region MCA, and may not be disposed in the interface region IA. The second buried contact BC2 may be disposed in the interface region IA, and the horizontal width of the second buried contact BC2 may be smaller than the horizontal width of the first buried contact BC1. Also, the height of the second buried contact BC2 may be lower than the height of the first buried contact BC1. For example, the lower end of the second buried contact BC2 may be positioned at a higher level than the lower end of the first buried contact BC1. The upper surface of the second buried contact BC2 may be located at the same level as the upper surface of the first buried contact BC1, but the present inventive concept is not limited thereto.

FIG. 14B is a top view of bit line structures (BLS) according to an example embodiment.

Referring to FIG. 14B, a step difference may not be present between the bit line structure BLS and the extension portion E in a semiconductor device 200b according to an example embodiment. For example, the first side surface Ea of the extension portion E may be a curved surface, and the first side surface BLSa may be continuous with the first side surface Ea. The second side surface Eb of the extension portion E may be curved, and the second side surface BLSb may be continuous with the second side surface Eb.

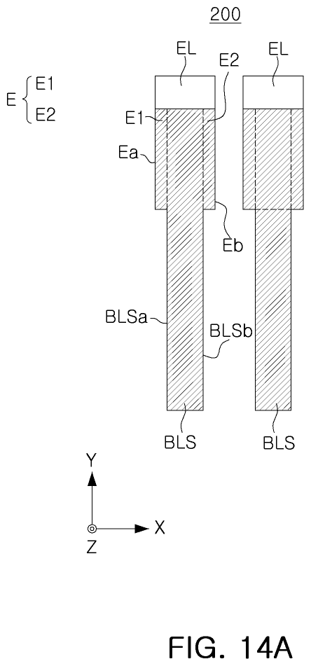

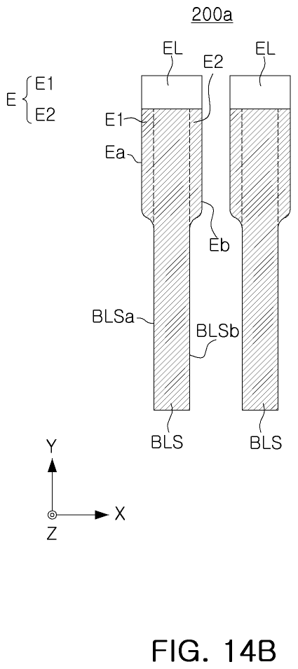

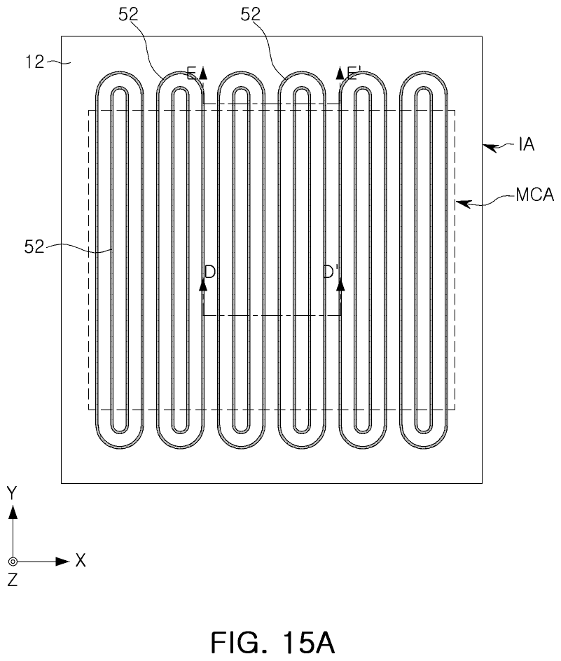

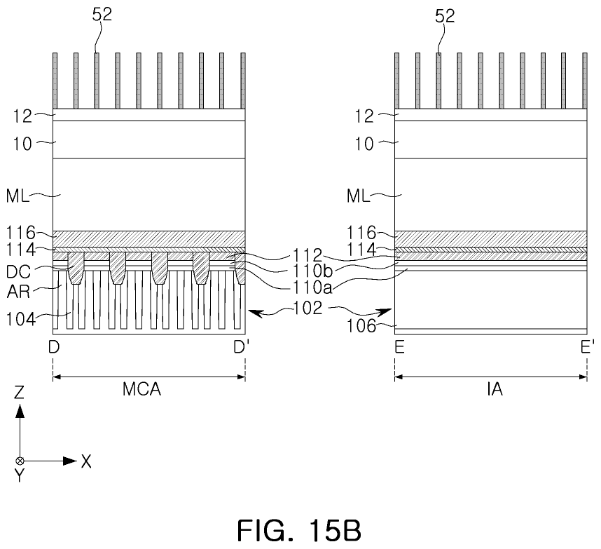

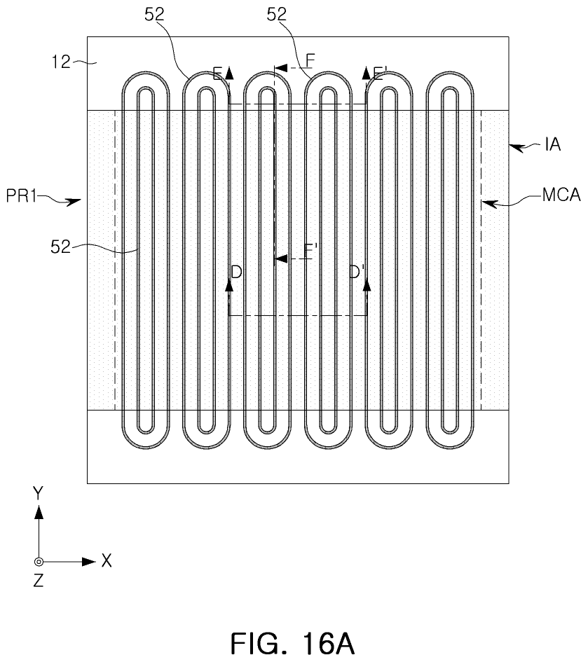

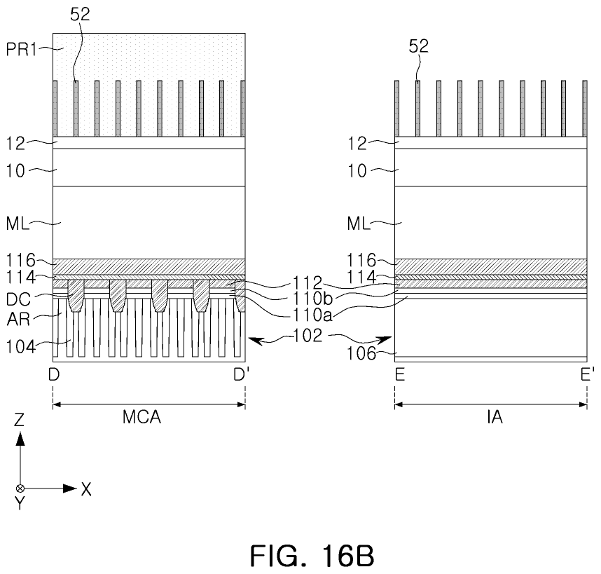

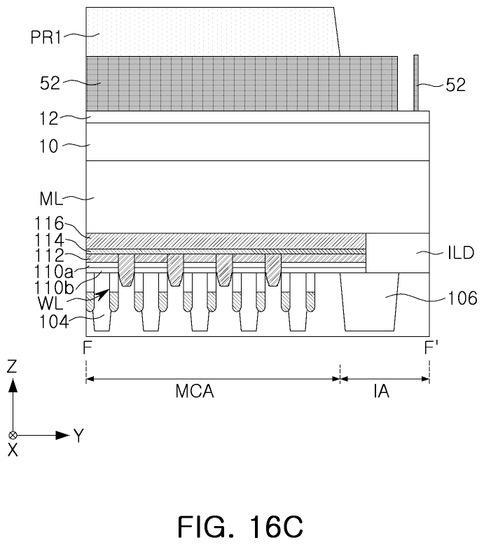

FIGS. 15A to 20 are plan views and cross-sectional views illustrating a method of manufacturing a semiconductor device according to an example embodiment according to a process sequence. In detail, FIGS. 15A, 16A, 17A, 18A, and 19A are plan views illustrating a method of manufacturing a semiconductor device corresponding to FIG. 13A. FIGS. 15B, 16B, 17B, 18B and 19B are vertical cross-sectional views taken along lines D-D′ and E-E′ of FIGS. 15A, 16A, 17A, 18A and 19A. FIGS. 16C, 17C, 18C, and 19C are vertical cross-sectional views taken along line F-F′ in FIGS. 16A, 17A, 18A, and 19A.

Referring to FIGS. 15A and 15B, a first spacer pattern 52 may be formed on the etch stop layer 12. The structure of FIGS. 15A and 15B may be formed by etching the first spacer material layer 50 in the resulting structure of FIGS. 6A and 6B to form a first spacer pattern 52 and removing the first mask pattern 20a and the first etch stop pattern 22a.

Referring to FIGS. 16A to 16C, a first photoresist PR1 covering the first spacer pattern 52 may be formed on the etch stop layer 12. The first photoresist PR1 may partially cover the etch stop layer 12 and the first spacer pattern 52. For example, the first photoresist PR1 may cover the cell region MCA and may expose the interface region IA spaced apart from the cell region MCA in the Y-direction.

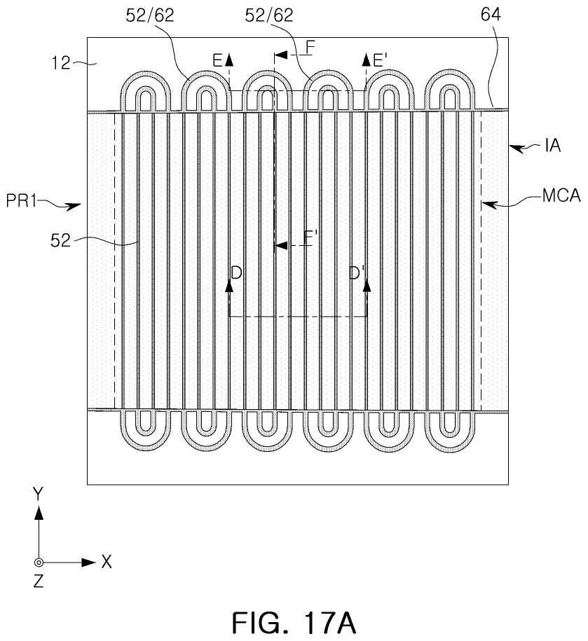

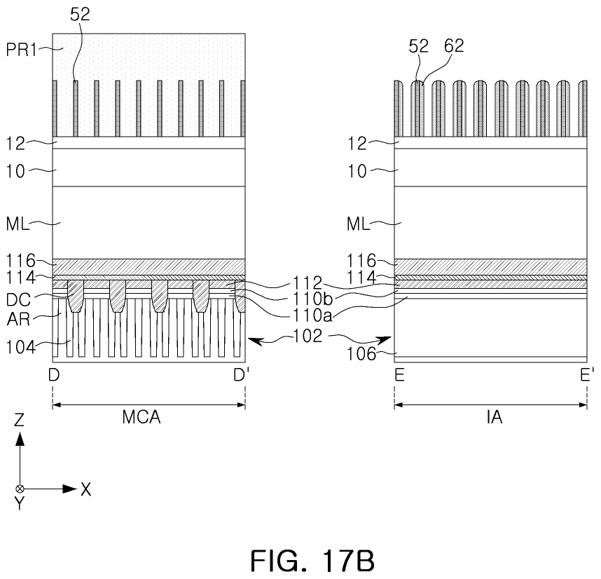

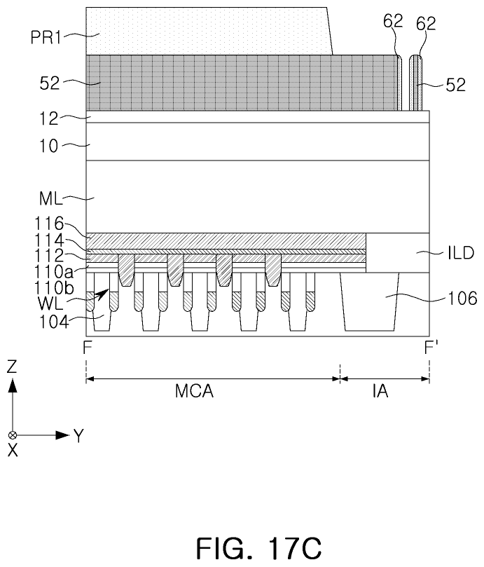

Referring to FIGS. 17A to 17C, a second spacer pattern 62 covering the first spacer pattern 52 may be formed in the interface region IA exposed by the first photoresist PR1. The second spacer pattern 62 may be formed by conformally forming an insulating material covering the cell region MCA and the interface region IA and anisotropically etching the insulating material. The second spacer pattern 62 covers the side surface of the first spacer pattern 52 and may extend along the side surface of the first spacer pattern 52. In an example embodiment, as illustrated in FIG. 9A, a remaining portion 64 may be formed on a side surface of the first photoresist PR1.

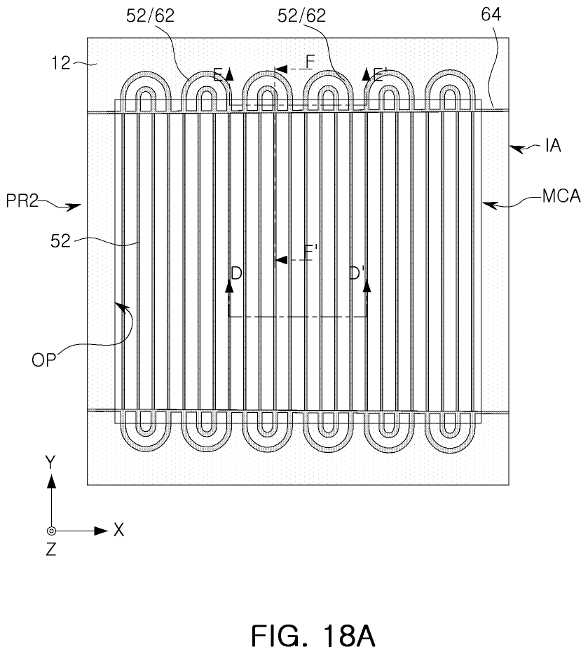

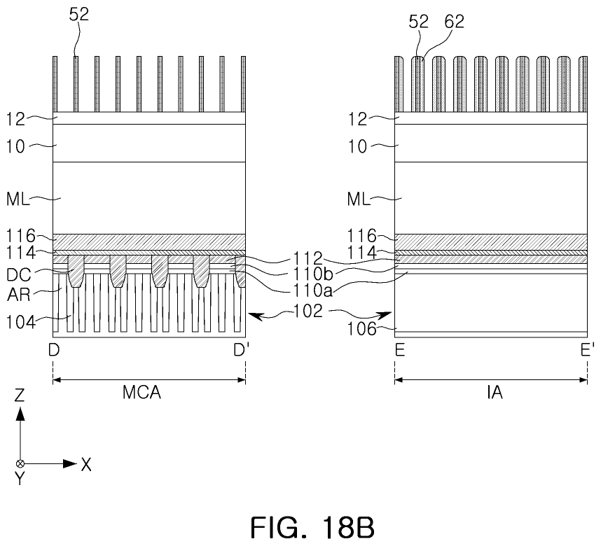

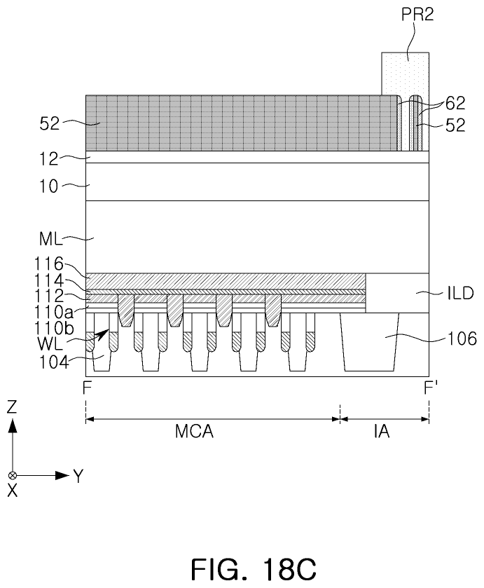

Referring to FIGS. 18A to 18C, the first photoresist PR1 may be removed, and the second photoresist PR2 may be formed in the interface region IA. The second photoresist PR2 may expose a portion of the interface region IA and the cell region MCA. For example, the second photoresist PR2 may include an opening OP. The opening OP may expose the cell region MCA, and further extend in the Y-direction from the cell region MCA toward the interface region IA to expose a portion of the interface region IA. The opening OP may partially expose the first spacer pattern 52, the second spacer pattern 62, and the remaining portion 64.

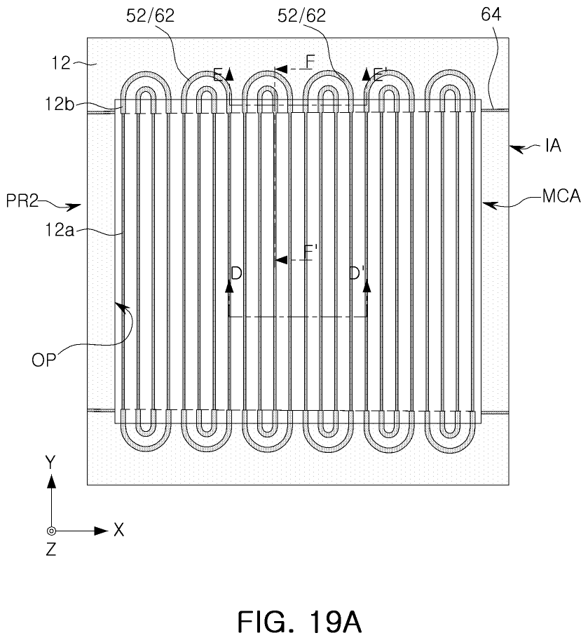

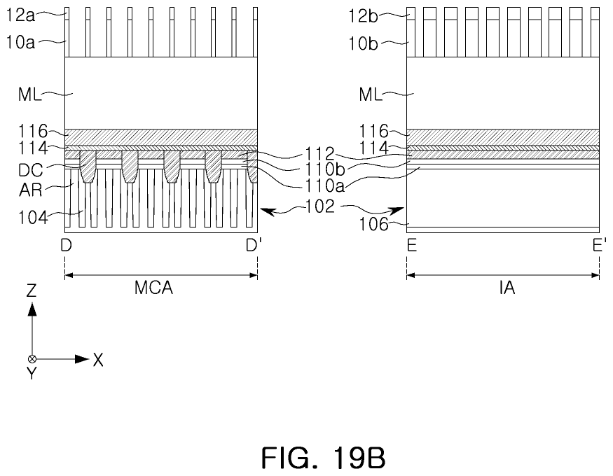

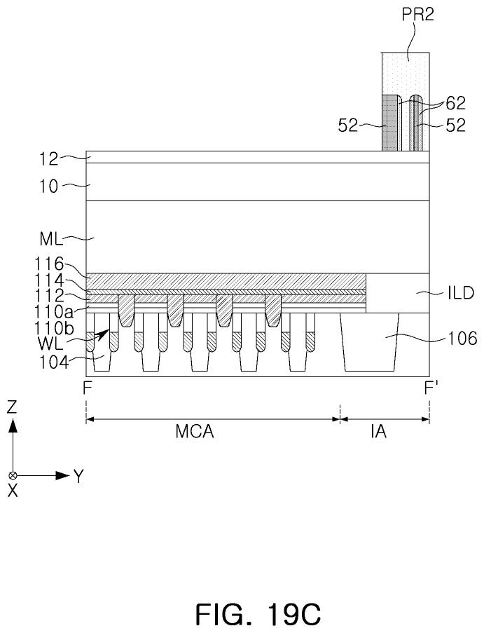

Referring to FIGS. 19A to 19C, the bit line mask layer 10 and the etch stop layer 12 are etched to form an internal mask pattern 10a on the mold layer ML, an internal etch stop pattern 12a on the internal mask pattern 10a, an external mask pattern 10b and an external etch stop pattern 12b on the external mask pattern 10b. The etching process may be performed using DPT. For example, the bit line mask layer 10 and the etch stop layer 12 may be patterned by an etching process using the first spacer pattern 52 and the second spacer pattern 62 as an etch mask. The internal mask pattern 10a and the internal etch stop pattern 12a may be formed in the cell region MCA and may extend along the first spacer pattern 52. The external mask pattern 10b and the external etch stop pattern 12b may be formed in the interface region IA and may extend along the first spacer pattern 52 and the second spacer pattern 62. Afterwards, the first spacer pattern 52 and the second spacer pattern 62 may be removed. When viewed in a plan view, the internal mask pattern 10a and the inner etch stop pattern 12a may have a line-and-space shape, and for example, may have a rod shape extending in the Y-direction. In a plan view, the external mask pattern 10b and the external etch stop pattern 12b may be disposed on both ends of the internal etch stop pattern 12a in the Y-direction. In a plan view, areas of the external mask pattern 10b and the external etch stop pattern 12b may be larger than areas of the internal mask pattern 10a and the external etch stop pattern 12b.

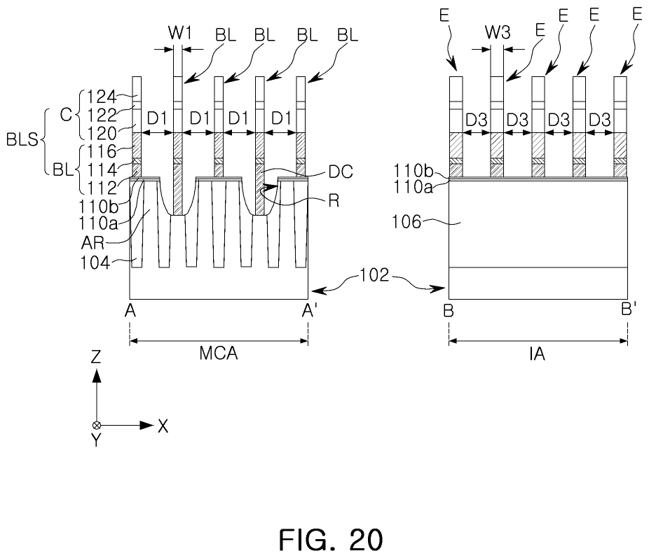

FIG. 20 is a vertical cross-sectional view corresponding to FIG. 13B and may correspond to a portion of the cross-sectional views illustrated in FIG. 19B. For convenience of description, the scale of some components of FIG. 20 may be different from that of FIG. 19B.

Referring to FIG. 20, the etching process described with reference to FIG. 12 may be performed. A bit line structure BLS may be formed in the cell region MCA, and an extension portion E connected to the bit line structure BLS may be formed in an interface region IA. The bit line structures BLS formed in the cell region MCA may have the same configuration as the bit line structures BLS illustrated in FIG. 12, and a detailed description thereof may be omitted.

The extension portions E may be formed on both ends of the bit line structure BLS in the Y-direction, respectively. A distance between the extension portions E may be a third distance. The extension portion E may have a third width W2 greater than the first width W1.

As illustrated in FIGS. 19A and 19B, by forming the horizontal width of the external mask pattern 10b and the external etch stop pattern 12b larger than the horizontal width of the internal mask pattern 10a and the internal etch stop pattern 12a, a horizontal width of the extension portion E may be greater than a horizontal width of the bit line structure BLS. Therefore, in the process of etching the first to third conductive layers 112, 114, and 116 and the mold layer ML, the first to third conductive layers 112, 114, and 116 may be prevented from being thinned and necked and from being broken. Therefore, the reliability of the device may be improved. In addition, a space in which a bit line contact (not illustrated) disposed on the extension portion E is to be formed may be secured.

As set forth above, according to example embodiments, a semiconductor device may include an extension portion disposed in an interface region and connected to a bit line. The extension portions have a width wider than the width of the bit lines and are spaced at smaller intervals. Therefore, the bit line and the extension portion may be prevented from being thinned or broken in the interface region, and the reliability of the device may be improved.

While example embodiments have been illustrated and described above, it will be apparent to those skilled in the art that modifications and variations could be made without departing from the scope of the present inventive concept as defined by the appended claims.

What is claimed is:

1. A semiconductor device comprising:
a substrate including a cell region and an interface region;
a gate electrode disposed within the cell region of the substrate and extending in a first horizontal direction that is parallel to an upper surface of the substrate;
a plurality of bit line structure pairs crossing the gate electrode and extending in a second horizontal direction that is parallel to the upper surface of the substrate and intersects the first horizontal direction, each bit line structure pair including a first bit line structure and a second bit line structure that are spaced apart from each other in the first horizontal direction; and
a plurality of extension portion pairs disposed within the interface region and spaced apart from each other in the first horizontal direction, each extension portion pair including a first extension portion and a second extension portion that are connected to the first bit line structure of a corresponding bit line structure pair and the second bit line structure thereof, respectively,
wherein the plurality of bit line structure pairs are spaced apart from each other by a first distance,
wherein, in each bit line structure pair, the first bit line structure and the second bit line structure are spaced apart from each other by the first distance,
wherein, in each extension portion pair, the first extension portion and the second extension portion are spaced apart from each other at a second distance less than the first distance, and
wherein the first distance and the second distance are measured in the first horizontal direction.

2. The semiconductor device of claim 1,
wherein a connected structure of the first extension portion and the first bit line structure has a first horizontal width greater than a second horizontal width of the first bit line structure, and
wherein the first horizontal width and the second horizontal width are measured in the first horizontal direction.

3. The semiconductor device of claim 1,
wherein the first extension portion protrudes in the first horizontal direction from one side of the first bit line structure.

4. The semiconductor device of claim 2,
wherein the connected structure is disposed in the interface region.

5. The semiconductor device of claim 2,
wherein a first central axis of the connected structure is offset from a second central axis of the first bit line structure in the first horizontal direction, and
wherein the first central axis of the first extension portion and the second central axis of the first bit line structure are parallel to the second horizontal direction.

6. The semiconductor device of claim 1,
wherein the plurality of extension portion pairs are spaced apart from each other by the first distance.

7. The semiconductor device of claim 1,
wherein the first extension portion is materially continuous with the first bit line structure, and
wherein the second extension portion is materially continuous with the second bit line structure.

8. The semiconductor device of claim 7,
wherein each of the first extension portion and the second extension portion includes a first conductive layer, a second conductive layer, and a third conductive layer that are sequentially stacked on the substrate.

9. The semiconductor device of claim 1, further comprising:
a first buried contact disposed in the interface region and disposed in a space between two adjacent extension portion pairs; and
a second buried contact disposed in the interface region and disposed in a space between the first extension portion and the second extension portion in each extension portion pair,
wherein a first horizontal width of the second buried contact is narrower than a second horizontal width of the first buried contact, and
wherein the first horizontal width and the second horizontal width are measured in the first horizontal direction.

10. The semiconductor device of claim 9,
wherein a lower end of the second buried contact is at a higher level than a lower end of the first buried contact.

11. The semiconductor device of claim 9, further comprising:
a third buried contact disposed in the cell region and disposed in a space between two adjacent bit line structure pairs; and
a fourth buried contact disposed in the cell region and disposed in a space between the first bit line structure and the second bit line structure in each bit line structure pair,
wherein a third horizontal width of the third buried contact and a fourth horizontal width of the fourth buried contact have the same width, and
wherein the third horizontal width and the fourth horizontal width are measured in the first horizontal direction.

12. The semiconductor device of claim 1, further comprising:
a first edge insulating structure contacting the first extension portion and the first bit line structure; and
a second edge insulating structure contacting the second extension portion and the second bit line structure.

13. A semiconductor device comprising:
a substrate including a cell region and an interface region;
a gate electrode disposed within the cell region of the substrate and extending in a first horizontal direction that is parallel to an upper surface of the substrate;
a plurality of bit line structures crossing the gate electrode and extending in a second horizontal direction intersecting the first horizontal direction, wherein the second horizontal direction is parallel to the upper surface of the substrate; and
a plurality of extension portions disposed in the interface region and connected to the plurality of bit line structures, respectively,
wherein a connected structure of each of the plurality of extension portions and a corresponding bit line structure of the plurality of bit line structures has a first horizontal width greater than a second horizontal width of the corresponding bit line structure,
wherein the first horizontal width and the second horizontal width are measured in the first horizontal direction,
wherein a first central axis of each the plurality of extension portions and a second central axis of the corresponding bit line structure extend in the second horizontal direction,
wherein the first central axis is aligned with the second central axis,
wherein the plurality of bit line structures are spaced apart from each other by a first distance,
wherein the plurality of extension portions are spaced apart from each other by a second distance less than the first distance, and
wherein the first distance and the second distance are measured in the first horizontal direction.

14. The semiconductor device of claim 13,
wherein each of the plurality of extension portions include a pair of extension portions which are connected to opposite side surfaces of a corresponding bit line structure of the plurality of bit line structures, respectively, and
wherein the corresponding bit line structure is disposed in a space between the pair of extension portions.

15. The semiconductor device of claim 13, further comprising:
a plurality of first buried contacts, each of the plurality of first buried contacts disposed in a space between corresponding two adjacent bit line structures of the plurality of bit line structures in the cell region; and
a plurality of second buried contacts, each of the plurality of second buried contacts disposed in a space between corresponding two adjacent extension portions of the plurality of extension portions in the interface region,
wherein a first horizontal width of each of the plurality of second buried contacts is less than a second horizontal width of each of the plurality of first buried contacts, and
wherein the first horizontal width and the second horizontal width are measured in the first horizontal direction.

16. The semiconductor device of claim 15,
wherein lower ends of the plurality of second buried contacts are at a higher level than lower ends of the plurality of first buried contacts.

17. The semiconductor device of claim 13,
wherein each of the plurality of extension portions is materially continuous with a corresponding bit line structure of the plurality of bit line structures.

18. A semiconductor device comprising:
a substrate including a cell region and an interface region;
a gate electrode disposed within the cell region of the substrate and extending in a first horizontal direction that is parallel to an upper surface of the substrate;
a first bit line structure crossing the gate electrode and extending in a second horizontal direction that is parallel to the upper surface of the substrate and intersects the first horizontal direction;
a second bit line structure crossing the gate electrode and extending in the second horizontal direction, wherein the second bit line structure is adjacent to the first bit line structure;
a first buried contact disposed in a space between the first bit line structure and the second bit line structure;
a landing pad electrically connected to the first buried contact and disposed on the first bit line structure;
a capacitor structure electrically connected to the landing pad and disposed on the landing pad; and
a pair of inner extension portions disposed within the interface region and connected to a first surface of the first bit line structure and a second surface of the second bit line structure, respectively,
wherein the first surface is adjacent to the second surface,
wherein the first bit line structure and the second bit line structure are spaced apart from each other by a first distance,
wherein the pair of inner extension portions are spaced apart from each other by a second distance less than the first distance, and
wherein the first distance and the second distance are measured in the first horizontal direction.

19. The semiconductor device of claim 18, further comprising:
a pair of spacer structures disposed on opposite sides of the first bit line structure,
wherein the first buried contact contacts one of the pair of spacer structures.

20. The semiconductor device of claim 18, further comprising:
a pair of outer extension portions disposed within the interface region and connected to a third surface of the first bit line structure and a fourth surface of the second bit line structure, respectively,
wherein the third surface of the first bit line structure is opposite to the first surface thereof, and
wherein the fourth surface of the second bit line structure is opposite to the second surface thereof.
